(19) United States
(12) Patent Application Publication
(10) Pub. No.: US 2026/0098898 A1
(43) Pub. Date: Apr. 9, 2026

(54) CARRIER MODULE, TRAY, AND TEST HANDLER

(71) Applicant: MIRAE Corporation, Cheonan-si (KR)

(72) Inventors: KYUNG TAE KIM, Cheonan-si (KR); UNG HYUN YOO, Cheonan-si (KR); KUK HYUNG LEE, Cheonan-si (KR)

(21) Appl. No.: 19/086,158

(22) Filed: Mar. 21, 2025

(30) Foreign Application Priority Data
Oct. 4, 2024 (KR) 10-2024-0134885
Nov. 20, 2024 (KR) 10-2024-0166100

(51) Int. Cl. G01R 31/28

(52) U.S. Cl. CPC G01R 31/2893

(57) ABSTRACT

Disclosed relates to a carrier module, a tray, and a test handler. The carrier module includes a carrier main body having a storage groove to store an electronic component and a bottom unit coupled to the carrier main body and supporting a bottom surface of the electronic component stored in the storage groove. The bottom unit includes N (N is a natural number greater than 1) bottom units, and a plurality of connection members coupled to the bottom member, and electrically connecting component terminals of the electronic component stored in the storage groove and test terminals of a test apparatus. First connection members to be connected to the component terminals are coupled to a first bottom member among the bottom members, and second connection members to be connected to the test terminals are coupled to a second bottom member among the bottom members.

### CROSS REFERENCE TO RELATED APPLICATION

The present application claims priority to Korean Patent Application No. 10-2024-0134885, filed Oct. 4, 2024, and Korean Patent Application No. 10-2024-0166100, filed Nov. 20, 2024 the entire contents of which are incorporated herein for all purposes by this reference.

### BACKGROUND OF THE INVENTION

### Field of the Invention

The present disclosure relates to a test handler handling an electronic component to test the electronic component.

### Description of the Related Art

A memory semiconductor device, non-memory semiconductor device, a central processing unit (CPU), etc., (hereinbelow, which will be referred to as the “electronic component”) are manufactured through some processes. For example, the electronic component may pass through some processes, such as a test process using a handling apparatus, such as a test handler, etc.

The test handler may perform a loading process, a test process, and an unloading process with respect to the electronic component. The loading process is a process of loading the electronic component from a user tray to a tray. The test process is a process of connecting the electronic component stored in the tray to a test apparatus. The test apparatus may perform a predetermined test with respect to the electronic component. The unloading process is a process of unloading the electronic component from the tray to the user tray. In this case, the test handler may grade the electronic component according to a test result.

In recent years, the need for miniaturization of electronic components has led to the development of electronic components called microchips. For example, electronic components such as high bandwidth memory (HBM), double data rate (DDR), graphics double data rate (GDDR), low power double data rate (LPDDR), etc. are actively developed.

As described above, as the electronic components are formed on a microscopic scale, component terminals of the electronic component to be connected to the test apparatus in the test process are formed at a narrow pitch. Accordingly, test terminals of the test apparatus to be connected to the component terminals should also be formed at a narrow pitch corresponding to the component terminals. Therefore, the costs to perform the test process on the electronic component formed on a microscopic scale becomes prohibitive, and the accuracy of the test process deteriorates.

### SUMMARY OF THE INVENTION

The present disclosure has been made keeping in mind the above problems occurring in the related art, and the present disclosure is intended to propose a carrier module, a tray, and a test handler, which are capable of reducing the costs of performing a test process on an electronic component formed on a microscopic scale.

Another objective of the present disclosure is to provide a carrier module, a tray, and a test handler, which are capable of improving the accuracy of a test process on an electronic component formed on a microscopic scale.

To solve the above-described objectives, the present disclosure has the following configuration.

According to the present disclosure, a carrier module may include: a carrier main body provided to store an electronic component and having a storage groove to store the electronic component; and a bottom unit coupled to the carrier main body and supporting a bottom surface of the electronic component stored in the storage groove. The bottom unit may include: N (N is a natural number greater than 1) bottom members; and a plurality of connection member coupled to the bottom member and electrically connecting component terminals of the electronic component stored in the storage groove and test terminals of a test apparatus. First connection members among the connection members may be coupled to a first bottom member among the bottom members. The first connection members are configured to be connected to the component terminals. Second connection members among the connection members may be coupled to a second bottom member among the bottom members. The second connection members are configured to be connected to the test terminals

A pitch between portions where the second connection members are connected to the test terminals may be wider than a pitch between portions where the first connection members are connected to the component terminals.

According to the present disclosure, the tray may include a tray main body; and a carrier module coupled to the tray main body.

According to the present disclosure, a test handler may include: a loading unit performing a loading process of loading an electronic component to be tested to a tray; and a test unit performing a test process of testing the electronic component stored in the tray. The loading unit stores the electronic component to be tested, in a carrier module included in the tray,

For the tray according to the present disclosure and the test handler according to the present disclosure, the carrier module may include: a carrier main body having a storage groove to store the electronic component; and a bottom unit coupled to the carrier main body and supporting a bottom surface of the electronic component stored in the storage groove. The bottom unit may include: N (N is a natural number greater than 1) bottom members; and a plurality of connection member coupled to the bottom member and electrically connecting component terminals of the electronic component stored in the storage groove and test terminals of a test apparatus. First connection members among the connection members may be coupled to a first bottom member among the bottom members. The first connection members are configured to be connected to the component terminals. Second connection members among the connection members may be coupled to a second bottom member among the bottom members. The second connection members are configured to be connected to the test terminals. A pitch between portions where the second connection members are connected to the test terminals may be wider than a pitch between portions where the first connection members are connected to the component terminals.

According to the present disclosure, the following effects can be provided.

The present disclosure is implemented to extend a pitch between portions connected to the test terminals of the test apparatus wider than a pitch between portions connected to the component terminals of the electronic component. Accordingly, since the present disclosure may widen a pitch of the test terminals, the present disclosure can improve the ease of the manufacturing process of the test apparatus, reducing the manufacturing costs of the test apparatus and reducing the processing costs of the test process. Furthermore, the present disclosure is implemented to perform the test process with the electronic components, which are electrically connected to the test apparatus at a wider pitch at the test terminals. Therefore, the present disclosure can improve the accuracy of the test process and ensure the reliability of test results of the test process.

### BRIEF DESCRIPTION OF THE DRAWINGS

FIG. 1 is a schematic block view of a test handler according to the present disclosure.

FIG. 2 is a schematic plan view of the test handler according to the present disclosure.

FIG. 3 is a schematic perspective view of a carrier module according to the present disclosure.

FIG. 4 is a schematic exploded perspective view of the carrier module according to the present disclosure.

FIG. 5 is a schematic partial side sectional view showing a bottom unit with respect to the carrier module according to the present disclosure, the view taken along line I-I of FIG. 4.

FIGS. 6 and 7 are schematic exploded side sectional views with respect to a bottom unit of FIG. 5.

FIG. 8 is a schematic plan view of the carrier module according to the present disclosure.

FIG. 9 is a schematic plan view showing movement of an electronic component to a reference position based on FIG. 8.

FIG. 10 is a schematic perspective view of an alignment unit for the carrier module according to the present disclosure.

FIG. 11 is a schematic side view of the alignment unit for the carrier module according to the present disclosure.

FIG. 12 is a schematic plan view illustrating the arrangement relationship between the alignment unit and a latch unit for the carrier module according to the present disclosure.

FIG. 13 is a schematic plan view enlarging part A in FIG. 8 for the carrier module according to the present disclosure and showing the alignment unit according to a deformed embodiment.

### DETAILED DESCRIPTION OF THE DISCLOSURE

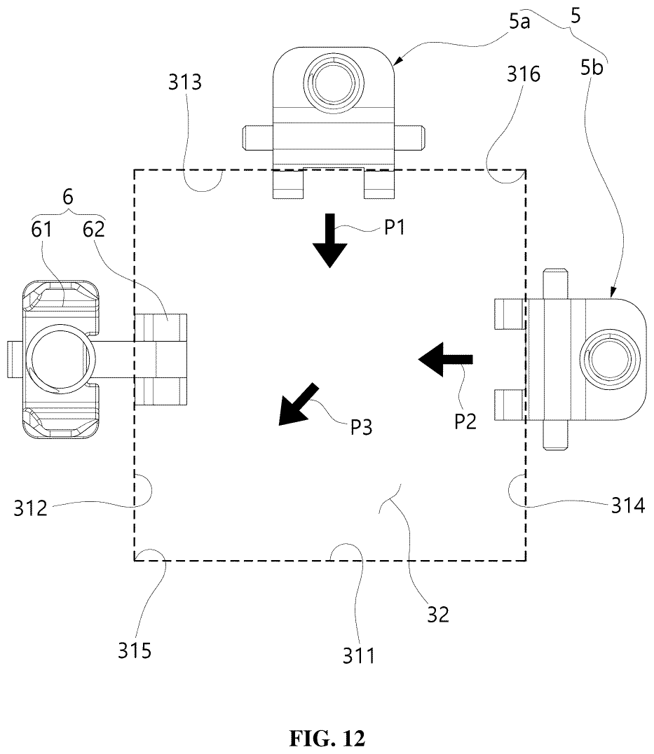

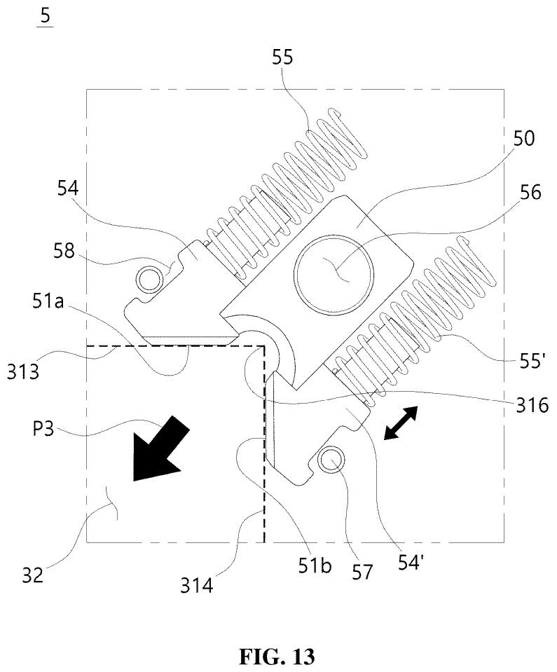

Hereinbelow, an embodiment of a test handler according to the present disclosure will be described in detail with reference to accompanying drawings. Meanwhile, a carrier module according to the present disclosure and a tray according to the present disclosure may be used when a test handler according to the present disclosure handles an electronic component, and will be described together with describing an embodiment of a test handler according to the present disclosure. The carrier module according to the present disclosure and the tray according to the present disclosure may be included in the test handler according to the present disclosure. Meanwhile, in FIGS. 12 and 13, the carrier main body is omitted, and the storage groove is indicated with dotted line.

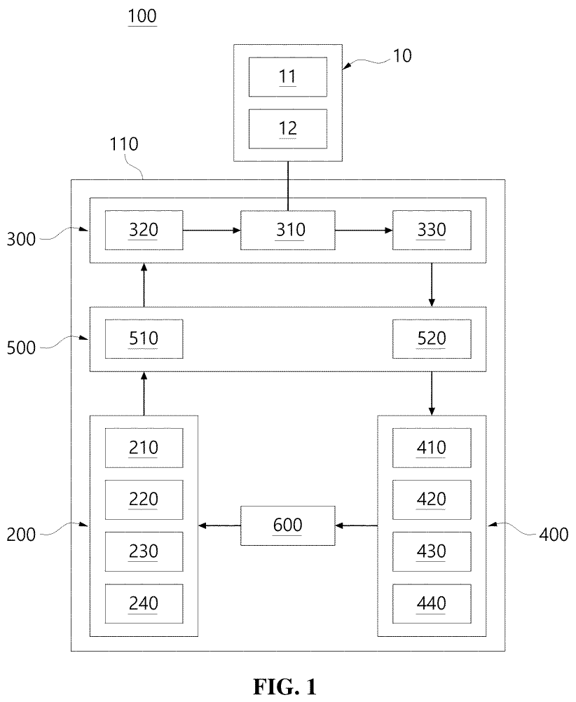

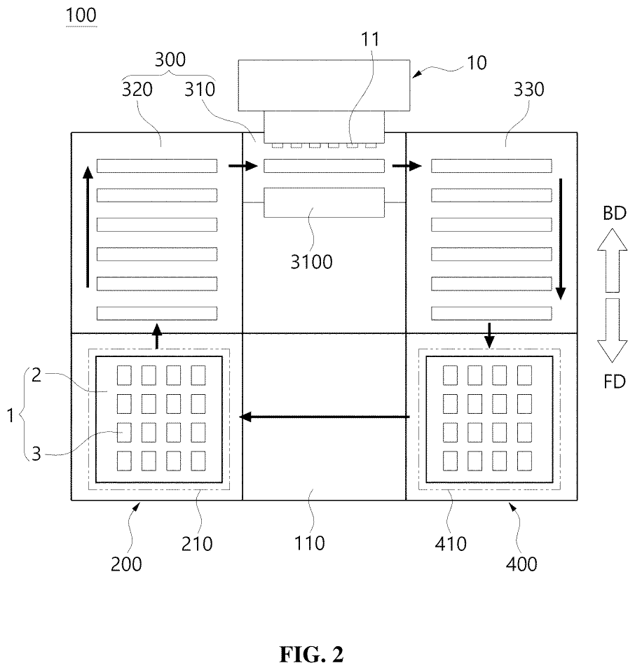

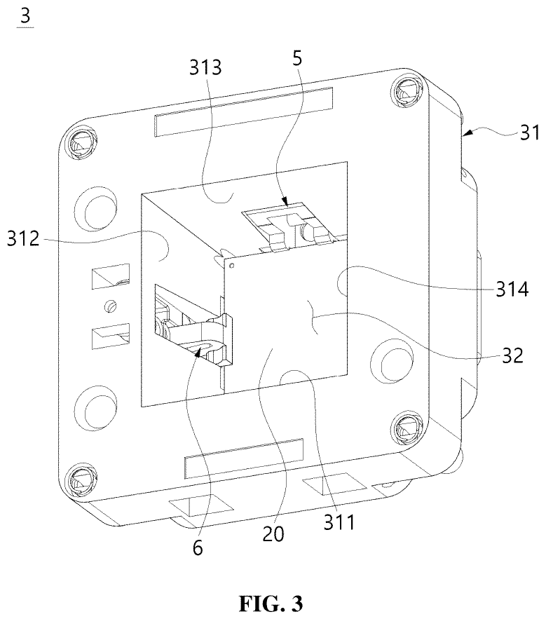

Referring to FIGS. 1 to 3, according to the present disclosure, a test handler 100 may perform a loading process of loading an electronic component 20 to be tested on a tray 1 (shown in FIG. 2), and a test process of testing the electronic component 20 loaded on the tray 1. The electronic component 20 may be a memory a memory semiconductor device, a non-memory semiconductor device, a central processing unit (CPU), and the like. The electronic component 20 may be a high bandwidth memory (HBM), a double data rate (DDR), a graphics double data rate (GDDR), a low power double data rate (LPDDR), and the like.

According to the present disclosure, the test handler 100 may include a loading unit 200 and a test unit 300.

Referring to FIGS. 1 to 3, the loading unit 200 may perform the loading process. The loading unit 200 may perform the loading process by loading the electronic component 20 to be tested, on the tray 1. The loading unit 200 may load the electronic component 20 to be tested, on the tray 1 located at the loading location 210. The loading location 210 is a place where the tray 1 is located when the loading process is performed. A loading stage (not shown) supporting the tray 1 may be installed at the loading location 210. The loading unit 200 may perform the loading process on the tray 1 laying horizontally. The loading unit 200 may be coupled to a main body 110. The main body 110 may be set up in a workplace.

The loading unit 200 may include a loading storage unit 220 and a loading picker 230.

The loading storage unit 220 may store one of a wafer ring, a reel, or a user tray. Accordingly, the loading picker 230 may pick up the electronic component 20 to be tested from one of a wafer ring, a reel, or a user tray. The loading storage unit 220 may be installed at the main body 110. The loading storage unit 220 may be installed at the main body 110.

The loading picker 230 may pick up the electronic component 20 to be tested from the loading storage unit 220 and store the electronic component 20 in the tray 1 located at the loading location 210. The loading picker 230 may pick up a plurality of electronic components 20 at the same time. The loading picker 230 may be moved along a first axial direction (X-axial direction) and a second axial direction (Y-axial direction). The first axial direction (X-axial direction) and the second axial direction (Y-axial direction) are perpendicular to each other. The loading picker 21 may be raised and lowered in a vertical direction. The vertical direction (Z-axial direction) may be perpendicular to both the first axial direction(X-axial direction) and the second axial direction(Y-axial direction). The plurality of electronic components 20 may be stored in the tray 1.

The loading unit 200 may include a loading buffer 230.

The loading buffer 230 may temporarily store the electronic component 20 to be tested. The loading picker 230 may include a first loading picker (not shown) transferring the electronic component 20 to be tested from the loading storage unit 220 to the loading buffer 230, and a second loading picker (not shown) transferring the electronic component 20 to be tested from the loading buffer 230 to the tray 1. The loading buffer 230 may be moved in at least one of the first axial direction (X-axial direction) and the second axial direction (Y-axial direction).

Referring to FIGS. 1 to 3, the test unit 300 may perform the test process. The test unit 300 may perform the test process by connecting the electronic component 20 stored in the tray 1 to the test apparatus 10. The test unit 300 may be coupled to a Hi-fix board included in the test apparatus 10. The test unit 300 may include a contact unit 3100 (shown in FIG. 2) that may connect the electronic component 20 stored in the tray 1 to the Hi-fix board. The contact unit 3100 may connect a plurality of electronic components 20 to the Hi-fix board at the same time. The test unit 300 may perform the test process on the tray 1 standing upright. The test unit 300 may be installed at the main body 110.

The test unit 300 may include a test chamber 310.

The test process may be performed in test chamber 310. A part of the test apparatus 10 may be inserted into the test chamber 310. The contact unit 3100 may be installed in the test chamber 310. The tray 1 may be disposed between the test apparatus 10 and the contact unit 3100 based on the second axial direction (Y-axial direction). The contact unit 3100 may connect the electronic component 20 stored in the tray 1 to the test apparatus 10 by transferring the tray 1 toward the test apparatus 10.

The test unit 300 may include a first chamber 320.

The first chamber 320 may transfer the tray 1, on which the loading process is performed, to the test unit 300. Based on the second axial direction (Y-axial direction), the first chamber 320 may be disposed at the rear side (direction of arrow BD) of the loading unit 200. The rear side (direction of arrow BD) may be disposed in parallel to the second axial direction (Y-axial direction). The first chamber 320 may adjust the temperature of the electronic component 20 stored in the tray 1 to a test temperature while transferring the tray 1 rearwards (direction of arrow BD). An operator can preset the test temperature in advance. When the test temperature is higher than room temperature, the first chamber 320 may adjust the temperature of the electronic component 20 stored in the tray 1 to the test temperature by heating. When the test temperature is lower than room temperature, the first chamber 320 may adjust the electronic component 20 stored in the tray 1 to the test temperature by cooling. The first chamber 320 and the test chamber 310 may be arranged in parallel to each other in the first axial direction (X-axial direction). The first chamber 320 may adjust the temperature of the electronic component 20 stored in the tray 1 while transferring the tray 1 standing upright. The tray 1 may be transferred through the first chamber 320 to the test chamber 310.

The test unit 300 may include a second chamber 330.

The second chamber 330 may restore the temperature of the electronic component 20 stored in the tray 1 to a temperature before it is adjusted to the test temperature. For example, the second chamber 330 may adjust the temperature of the electronic component 20 stored in the tray 1 to room temperature by cooling or heating. When the temperature of the electronic component 20 stored in the tray 1 is adjusted to the test temperature through the heating by the first chamber 320, the second chamber 330 may cool the electronic component 20 stored in the tray 1. When the first chamber 320 adjusts the temperature of the electronic component 20 stored in the tray 1 to the test temperature by cooling, the second chamber 330 may heat the electronic component 20 stored in the tray 1. The second chamber 330 may adjust the temperature of the electronic component 20 stored in the tray 1 while transferring the tray 1 standing upright. The second chamber 330 may adjust the temperature of the electronic component 20 stored in the tray 1 while transferring the tray 1 forwards (direction of arrow FD). The forward direction (direction of arrow FD) and the rearward direction (direction of arrow BD) may be directions parallel to the second axial direction (Y-axial direction) and opposite to each other. The second chamber 330, the test chamber 310, and the first chamber 320 may be disposed in line with each other in the first axial direction (X-axial direction). The tray 1 may be transferred through both the first chamber 320 and the test chamber 310 to the second chamber 330.

Referring to FIGS. 1 to 3, according to the present disclosure, the test handler 100 may include the unloading unit 400.

The unloading unit 400 may perform an unloading process. The unloading process may be performed by unloading the tested electronic component 20 from the tray 1. The unloading unit 400 may be disposed at the front side (direction of arrow FD) with respect to the second chamber 330. The unloading unit 400 may unload the tested electronic component 20 from the tray 1 located at an unloading location 410. The unloading location 410 may be a location where the tray 1 is located during the unloading process. An unloading stage (not shown) supporting the tray 1 may be installed at the unloading location 410. The unloading unit 400 may perform the unloading process to the tray 1 laying horizontally. The unloading unit 400 may be coupled to the main body 110. The unloading unit 400 and the loading unit 200 may be disposed at locations spaced apart from each other in the first axial direction (X-axial direction). The tray 1 may be transferred from the second chamber 330 to the unloading unit 400, and after the unloading process is performed by the unloading unit 400, the tray 1 may be transferred to the loading unit 200.

The unloading unit 400 may include an unloading storage unit 420 and an unloading picker 430.

The unloading storage unit 420 may store one of a wafer ring, a reel, or a user tray. The unloading picker 430 may store the tested electronic component 20 in one of a wafer ring, a reel, or a user tray, which is located in the unloading storage unit 420. The unloading storage unit 420 may be installed at the main body 110. The unloading storage unit 420 may be installed outside the main body 110. The unloading storage unit 420 and the loading storage unit 220 may include the same type of storage means. For example, according to the present disclosure, the test handler 100 may pick up the electronic components 20 to be tested from the wafer ring and place the tested electronic components 20 on the wafer ring. The unloading storage unit 420 and the loading storage unit 220 may include different types of storage means. For example, according to the present disclosure, the test handler 100 may pick up the electronic components 20 to be tested from the wafer ring and place the tested electronic components 20 on the reel or user tray.

The unloading picker 430 may pick up the tested electronic component 20 from tray 1 located at the unloading location 410 and then store the electronic component 20 in one of the wafer rings, reel, or user tray, which is located in the unloading storage unit 420. The unloading picker 430 may be transferred along the first axial direction (X-axial direction) and the second axial direction (Y-axial direction). The unloading picker 430 may be raised and lowered in the vertical direction. The unloading picker 430 may pick up a plurality of electronic components 20 at the same time.

The unloading unit 400 may include an unloading buffer 440.

The unloading buffer 440 may temporarily store the tested electronic component 20. The unloading picker 430 may include a first unloading picker (not shown) transferring the tested electronic component 20 from the tray 1 to the unloading buffer 440 and a second unloading picker (not shown) transferring the tested electronic component 20 from the unloading buffer 440 to the unloading storage unit 420. The unloading buffer 430 may be moved in at least one of the first axial direction (X-axial direction) and the second axial direction (Y-axial direction).

Referring to FIGS. 1 to 3, according to the present disclosure, the test handler 100 may include a rotating unit 550 (shown in FIG. 1).

The rotating unit 550 may rotate the tray 1. The rotating unit 550 may rotate the tray 1 and switch the tray 1 between a horizontal state and a vertical state. The rotating unit 550 may allow both the loading process and the unloading process to be performed with respect to the tray 1 laying horizontally. The rotating unit 550 may allow the test process to be performed with the tray 1 standing upright. By the rotating unit 550, the process of adjusting the temperature of the electronic component 20 may be performed in each of the first chamber 320 and the second chamber 330 while transferring the tray 1 standing upright.

The rotating unit 550 may include a loading rotator 510 (shown in FIG. 1) and an unloading rotator 520 (shown in FIG. 1).

The loading rotator 510 may rotate the tray 1 in the horizontal state and switch the tray into the vertical state. After the loading rotator 510 is supplied with the tray 1 in the horizontal state from the loading unit 200, the loading rotator 510 may rotate the tray 1 and switch the tray 1 into the vertical state. Thereafter, the loading rotator 510 may supply the tray 1 in the vertical state to the first chamber 320. The loading rotator 510 may be disposed between the loading unit 200 and the first chamber 320. The loading rotator 510 may be disposed at the rear side (direction of arrow BD) with respect to the loading unit 200 and disposed above the first chamber 320.

The unloading rotator 520 may rotate the tray 1 in the vertical state and switch the tray 1 into the horizontal state. The unloading rotator 520 may be supplied with the tray 1 in the vertical state from the second chamber 330, and then rotate the tray 1 and switch the tray 1 into the horizontal state. Thereafter, the unloading rotator 520 may supply the tray 1 in the horizontal state to the unloading unit 400. The unloading rotator 520 may be disposed between the unloading unit 400 and the second chamber 330. The unloading rotator 520 may be disposed at the rear side (direction of arrow BD) with respect to the unloading unit 400 and disposed above the second chamber 330. With respect to the first axial direction (X-axial direction), the unloading rotator 520 and the loading rotator 510 may be disposed to be spaced apart from each other.

Although not shown in the drawings, the rotating unit 550 may switch the tray 1 between the vertical state and the horizontal state by using one rotator. In this case, the rotator may rotate the tray 1 transferred from the loading unit 200 and switch the tray 1 from the horizontal state to the vertical state, and then supply the tray 1 to the first chamber 320. The rotator may rotate the tray 1 transferred from the second chamber 330 and switch the tray 1 from the vertical state to the horizontal state, and then supply the tray 1 to the unloading unit 400.

Referring to FIGS. 1 to 3, according to the present disclosure, the test handler 100 may include a transfer unit 600 (shown in FIG. 1).

The transfer unit 600 may transfer the tray 1. The transfer unit 600 may transfer the tray 1 by pushing the tray in a transfer direction. The transfer unit 600 may transfer the tray 1 by pulling the tray in the transfer direction. The transfer unit 600 may transfer the tray 1 to the loading unit 200, the test unit 300, and the unloading unit 400. In this process, the loading process, the test process, and the unloading process may be performed to the tray 1. After the unloading process is finished, the transfer unit 600 may transfer the tray 1 from the unloading unit 400 to the loading unit 200. As described above, the tray 1 may be circulated among the loading unit 200, the test unit 300, and the unloading unit 400 by the transfer unit 600. When the first chamber 320 is provided, the transfer unit 600 may transfer the tray 1 from the loading unit 200 to the test chamber 310 through the first chamber 320. When the second chamber 330 is provided, the transfer unit 600 may transfer the tray 1 from the test chamber 310 to the unloading unit 400 through the second chamber 330. When the rotating unit 550 is provided, the transfer unit 600 may transfer the tray 1 from the loading unit 200 to the first chamber 320 through the rotating unit 550. Furthermore, the transfer unit 600 may transfer the tray 1 from the second chamber 330 to the unloading unit 400 through the rotating unit 550.

At this point, according to the present disclosure, the test handler 100 may be implemented to be suitable for handling the electronic component 20 that is a microchip formed to have a microscopic scale such as a HBM, a DDR, a GDDR, a LPDDR, and the like. To this end, according to the present disclosure, the test handler 100 may use the tray 1 to be described below.

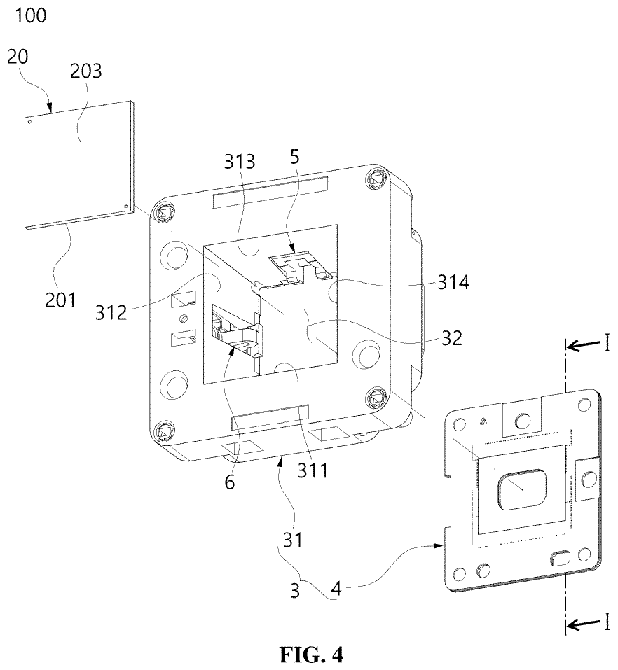

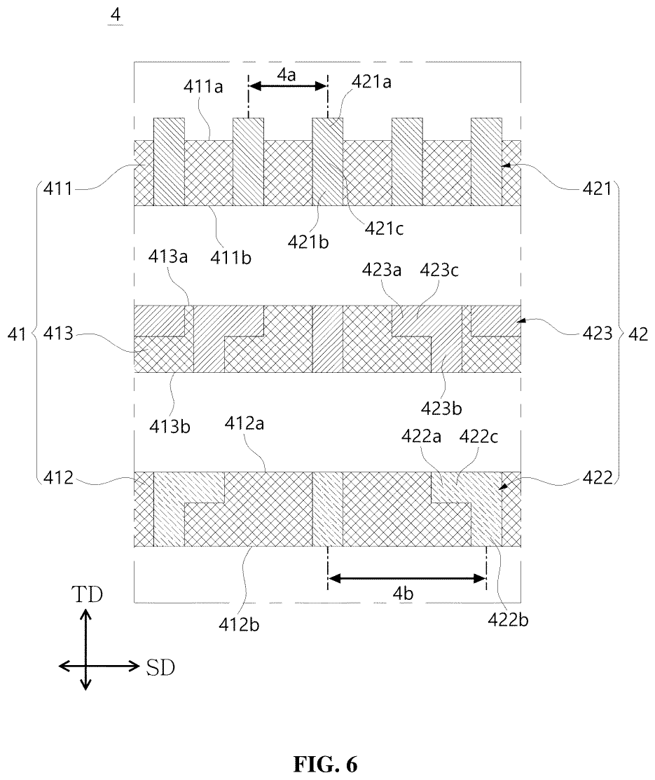

Referring to FIGS. 1 to 6, the tray 1 may store the electronic component 20. The tray 1 may include a tray main body 2 (shown in FIG. 2) and a carrier module 3.

The tray main body 2 may support the carrier module 3. The carrier module 3 may store the electronic component 20. The carrier module 3 may be supported by the tray main body 2 by being coupled to the tray main body 2. The tray main body 2 may be entirely formed in a quadrilateral plate but is not limited thereto, and the tray main body 2 may be formed in different shapes, such as a discus shape, etc., that can support the carrier module 3.

The tray main body 2 may include a carrier hole (not shown). The carrier hole may be formed through the tray main body 2. The carrier module 3 may be inserted into the carrier hole and coupled to the tray main body 2. The carrier module 3 may be coupled to the tray main body 2 with an elastomer (not shown) such as a spring, etc. Accordingly, the carrier module 3 may be coupled to the tray main body 2 to be elastically movable using an elastic force of the elastomer. Therefore, when the test process is performed, the carrier module 3 is moved toward the test apparatus 10 by pressure provided by the contact unit 3100 so that the electronic component 20 is connected to the test apparatus 10. When the pressure provided by the contact unit 3100 is removed, the carrier module 3 may be moved to its original location by using the restoring force of the elastomer.

A plurality of carrier modules 3 may be coupled to the tray main body 2. Although FIG. 2 shows the tray main body 2 to which 16 carrier modules 3 are coupled, the present disclosure is not limited thereto, and 64, 128, 256, 512, or more carrier modules 3 may be coupled to the tray main body 2. The number of carrier modules 3 coupled to the tray main body 2 may correspond to the number of electronic components 20 simultaneously connected to the test apparatus 10 and tested. The carrier modules 3 may be coupled in a matrix to the tray main body 2. For example, as shown in FIG. 2, the carrier modules 3 may be coupled in a matrix of 4×4 to the tray main body 2. Although not shown in the drawing, the carrier modules 3 may be coupled to the tray main body 2 in a matrix of 8×8, 8×16, 16×16, 16×32, or the like.

Referring to FIGS. 1 to 6, the carrier module 3 may store the electronic component 20. The loading unit 200 may perform the loading process by loading the electronic component 20 on the carrier module 3. The test unit 300 may perform the test process by connecting the electronic component 20 stored in the tray 1 to a test apparatus 10. The unloading process may perform the unloading process by unloading the electronic component 20 from the carrier module 3.

The carrier module 3 may include a carrier main body 31.

The carrier main body 31 may form the overall exterior of the carrier module 3. As the carrier main body 31 is coupled to the tray main body 2, the carrier module 3 may be supported by the tray main body 2.

A storage groove 32 may be formed in the carrier main body 31. The storage groove 32 may be formed through the carrier main body 31. The storage groove 32 may have a form corresponding to the electronic component 20.

The carrier module 3 may include a bottom unit 4.

The bottom unit 4 may be coupled to the carrier main body 31. The bottom unit 4 may be coupled to one portion of the carrier main body 31, blocking the storage groove 32. Accordingly, the electronic component 20 may remain stored in the storage groove 32 by being inserted into the storage groove 32 and supported by the bottom unit 4. In this case, the bottom unit 4 may support a bottom surface 201 of the electronic component 20. The bottom surface 201 of the electronic component 20 may be a portion where a component terminal 202 to be connected to the test apparatus 10 is provided. A plurality of component terminals 202 may be disposed on the bottom surface 201 of the electronic component 20. Meanwhile, the test apparatus 10 may include a test socket 11 corresponding to the carrier module 3. The test socket 11 may include a test terminal 12 to which the component terminal 202 is connected. The test socket 11 may include a plurality of test terminals 12. When the test terminals 12 and the component terminals 202 are connected one to one, the test process may be performed.

At this point, for the electronic component 20, which is a microchip formed on a microscopic scale, such as HBM, DDR, GDDR, LPDDR, etc., a pitch thereof where the component terminals 202 are spaced from each other may be formed narrow. For example, when the electronic component 20 is a HBM, a pitch of the component terminals 202 may be equal to or greater than 0.14 mm and less than 0.17 mm. To correspond to the pitch between the component terminals 202, a pitch between the test terminals 12 should also be formed narrow. Therefore, Not only is the manufacturing process of the test apparatus 10 more difficult, but the manufacturing costs of the test apparatus 10 increase, increasing the process costs of the test process. Furthermore, when the test terminals 12 and the component terminals 202 are spaced from each other at a narrow pitch, the test terminals 12 and the component terminals 202 should be individually connected to each other, and poor connection, etc. is more likely to occur, and this may reduce the accuracy of the test process.

To solve this problem, the bottom unit 4 may extend a pitch so that a pitch (hereinbelow, which will be referred to as the “test pitch 4b”) between portions connected to the test terminals 12 is formed wider than a pitch (hereinbelow, which will be referred to as the “component pitch 4a”) between portions connected to the component terminals 202. Accordingly, according to the present disclosure, the test handler 100 may be implemented to form a pitch of the test terminals 12 wider than a pitch of the component terminals 202. Therefore, according to the present disclosure, the test handler 100 can improve the ease of the manufacturing process with respect to the test apparatus 10, and reduce manufacturing cost with respect to the test apparatus 10 to reduce processing cost with respect to the test process. Furthermore, the test handler 100 according to the present disclosure may perform the test process on the electronic component 20 electrically connected to the test terminals 12 at a wider pitch than the pitch of the component terminals 202. Therefore, the test handler 100 according to the present disclosure may improve the accuracy of the test process and improve the reliability of the test results of the test process. In this case, the electronic component 20 may be connected to the bottom unit 4, the bottom unit 4 is connected to the test terminals 12, and this allows the electronic component 20 to be electrically connected to the test terminals 12. For example, the component pitch 4a may be formed greater than or equal to 0.14 mm and less than 0.17 mm, like the component terminals 202. In this case, portions where the bottom unit 4 is connected to the component terminals 202 may be formed to form the same arrangement at the same positions as the component terminals 202. The test pitch 4b may be formed greater than or equal to 0.4 mm less than 1 mm, like the test terminals 12. In this case, portions where the bottom unit 4 is connected to the test terminals 12 may be formed to form the same arrangement at the same positions as the test terminals 12. The portions where the bottom unit 4 is connected to the component terminals 202 and the portions where the bottom unit 4 is connected to the test terminals 12 may be formed to form different pitches, different positions, and different arrangements.

The bottom unit 4 may include a bottom member 41 and a connection member 42.

The bottom member 41 may support the bottom surface 201 of the electronic component 20 stored in the storage groove 32. The bottom member 41 may be coupled to the carrier main body 31. The bottom member 41 may be coupled to the carrier main body 31 by a fastening means such as a bolt, and the like. The bottom unit 4 may include N (N is a natural number greater than 1) bottom members 41. The bottom members 41 may be coupled to each other so as to be connected to each other. The bottom members 41 may be coupled to be stacked in a direction in which the electronic component 20 stored in the storage groove 32 and the bottom unit 4 are disposed.

The connection members 42 may electrically connect the component terminals 202 and the test terminals 12 to each other. The connection members 42 may be coupled to the bottom members 41. The connection members 42 is connected to the component terminals 202 and the test terminals 12 while being coupled to the bottom members 41, electrically connecting the component terminals 202 and the test terminals 12 to each other. The connection members 42 may be made of a conductive material. The bottom unit 4 may include a plurality of connection members 42. The connection members 42 may be respectively coupled to the bottom members 41. The connection members 42 may electrically connect the component terminals 202 and the test terminals 12 to each other.

Among the connection members 42, first connection members 421 may be coupled to a first bottom member 411 among the bottom members 41. The first bottom member 411 may be, among the bottom members 41, disposed closest to the electronic component 20 stored in the storage groove 32. Accordingly, the first connection members 421 may serve to be connected to the component terminals 202 of the electronic component 20 stored in the storage groove 32. The number of the first connection members 421 may be provided same as the number of the component terminals 202. The first connection members 421 may be coupled to the first bottom member 411 so as to be disposed at spaced locations. The first connection members 421 may be disposed to be exposed toward a first surface 411a of the first bottom member 411 and disposed to be exposed toward a second surface 411b of the first bottom member 411. The first surface 411a of the first bottom member 411 may be disposed to face the component terminals 202 of the electronic component 20 stored in the storage groove 32. The second surface 411b of the first bottom member 411 may be disposed to face the test terminals 12.

Second connection members 422 among the connection members 42 may be coupled to a second bottom member 412 of the bottom members 41. The second bottom member 412 among the bottom members 41 may be disposed closer to the test apparatus 10. Accordingly, the second connection members 422 may serve to be respectively connected to the test terminals 12. The number of second connection members 422 may be provided equal to the number of test terminals 12. In this case, the number of test terminals 12 and the number of component terminals 202 may be equal to each other. The second connection members 422 may be coupled to the second bottom member 412 while being disposed at spaced locations. The second connection members 422 may be disposed to be exposed to a first surface 412a of the second bottom member 412 and disposed to be exposed to a second surface 412b of the second bottom member 412. The first surface 412a of the second bottom member 412 may be disposed to face the first bottom member 411. The second surface 412b of the second bottom member 41 may be disposed to face the test apparatus 10.

A pitch between portions where the second connection members 422 are connected to the test terminals 12 may be formed wider than a pitch between portions where the first connection members 421 are connected to the component terminals 202. Therefore, according to the present disclosure, the test handler 100 is implemented to widen a pitch between the test terminals 12 wider than a pitch between the component terminals 202. Therefore, according to the present disclosure, the test handler 100 may reduce the process costs of the test process by reducing the manufacturing costs of the test apparatus 10, and may increase the accuracy of the test process. In this case, a pitch between portions where the second connection members 422 are connected to the test terminals 12 may be the test pitch 4b. A pitch between portions where the first connection members 421 are connected to the component terminals 202 may be the component pitch 4a.

Third connection members 423 among the connection members 42 may be coupled to a third bottom member 413 of the bottom members 41. The third bottom member 413 is disposed between the first bottom member 411 and the second bottom member 412. The number of third connection members 423, the number of second connection members 422, and the number of first connection members 421 may be equal to each other. The third connection members 423 may be coupled to the third bottom member 413 so as to be disposed at spaced locations. The third connection members 42d may be disposed to be exposed to a first surface 413a of the third bottom member 413 and disposed to be exposed to a second surface 413b of the third bottom member 413. The first surface 413a of the third bottom member 412 may be disposed to face the first bottom member 411. The second surface 413b of the third bottom member 413 may be disposed to face the second bottom member 412.

A first portion of each third connection member 423 may be electrically connected to each first connection member 421, and a second portion of each third connection member 423 may be electrically connected to each second connection member 422. Therefore, the third connection members 423 may electrically connect the first connection members 421 and the second connection members 422 to each other. The third connection members 423 may be brought in contact with and connected to the first connection members 421 and brought in contact with and connected to the second connection members 422. In this case, the bottom unit 4 may include 3 bottom members 41. The bottom unit 4 may include 4 or more bottom members 41. In this case, a first portion of each third connection member 423 and each first connection member 421 may be electrically connected to each other through each connection member 42. A second portion of each third connection member 423 and each second connection member 422 may be electrically connected to each other through each connection member 42.

A part of or the entire third connection members 423 may be formed such that a pitch of portions exposed from the second surface 413b of the third bottom member 413 is wider than a pitch between portions exposed from the first surface 413a of the third bottom member 413. In other words, a part or the entire third connection members 423 extend from the first surface 413a of the third bottom member 413 to the second surface 413b of the third bottom member 413, increasing the pitch. Therefore, according to the present disclosure, the test handler 100 is implemented to widen a pitch between the test terminals 12 wider than a pitch between the component terminals 202 by using the third connection members 423. In this case, a part of or the entire second connection members 422 may be formed to widen a pitch of portions exposed from the second surface 412b of the second bottom member 412 wider than a pitch between portions exposed from the first surface 412a of the second bottom member 412. In other words, a part or the entire second connection members 422 extend from the first surfaces 412a of the second bottom member 412 to the second surfaces 412b of the second bottom member 412, increasing the pitch.

Accordingly, according to the present disclosure, the test handler 100 is implemented to widen a pitch between the test terminals 12 wider than a pitch between the component terminals 202 by using the third connection members 423 and the second connection members 422. Therefore, according to the present disclosure, the test handler 100 may have the test pitch 4b implemented through step-extension using a pitch extension of the third connection members 423 and pitch extension of the second connection members 422. Accordingly, in the test handler 100 according to the present disclosure, the test pitch 4b may be formed wider, and the test terminals 12 may be implemented with a wider pitch. Therefore, according to the present disclosure, the test handler 100 may further reduce the process costs of the test process by further reducing the manufacturing costs of the test apparatus 10, and may further increase the accuracy of the test process.

Furthermore, according to the present disclosure, the test handler 100 may be implemented such that pitch extension from the component pitch 4a to the test pitch 4b is performed while being shared by the third bottom member 413 and the second bottom member 412. In this case, pitch extension at the third bottom member 413 is performed by the third connection members 423, and pitch extension at the second bottom member 412 may be performed by the second connection members 422. Accordingly, in comparison to a comparative example in which pitch extension from the component pitch 4a to the test pitch 4b is performed in one bottom member 41, the test handler 100 according to the present disclosure may improve the ease of an operation of coupling the connection members 42 to the bottom members 41, and improve the ease of the arrangement of the connection members 42 for pitch extension. Meanwhile, pitch extension performed by the third connection members 423 and pitch extension performed by the second connection members 422 may be implemented in the same extension rate. The pitch extension performed by the third connection members 423 and the pitch extension performed by the second connection members 422 may be implemented in the same extension rate.

Each third connection member 423 may include an inner member 423a, an outer member 423b, and a connection member 423c.

The inner member 423a may be disposed to face each first connection member 421. The outer member 423b may be disposed to face each second connection member 422. The connection member 423c may connect the inner member 423a and the outer member 423b to each other. Through the connection member 423c, the inner member 423a and the outer member 423b may be electrically connected to each other.

A part of the third connection members 423 may be formed such that the inner member 423a, the connection member 423c, and the outer member 423b form a straight line in a thickness direction (TD-axial direction) of the third bottom member 413. The third connection members 423, as described above, may electrically connect the first connection members 421 and the third connection members 423 to each other without pitch expansion. Meanwhile, the thickness direction (TD-axial direction) may be an axial direction in parallel to a direction in which the first surface 413a of the third bottom member 413 and the second surface 413b of the third bottom member 413 are spaced apart from each other.

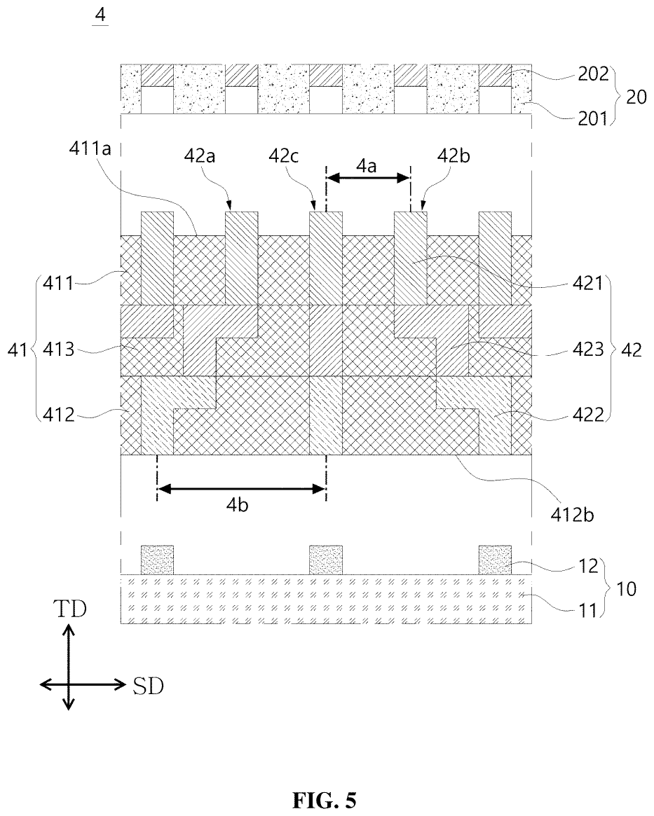

A part of the third connection members 423 may be disposed at locations where the inner member 423a and the outer member 423b are spaced in a surface direction (SD-axial direction) of the third bottom member 413. In this case, the connection member 423c may extend in the surface direction (SD-axial direction) and connect the inner member 423a and the outer member 423b to each other. The third connection members 423 formed as described above may increase a pitch by using the connection member 423c and electrically connect the first connection members 421 and the third connection members 423 to each other. Meanwhile, the surface direction (SD-axial direction) may be an axial direction perpendicular to the thickness direction (TD-axial direction). FIG. 5 is a view showing the connection member 423c extending leftward and rightward based on the inner member 423a, but the present disclosure is not limited thereto, and the connection member 423c may extend in one direction of radial directions based on the inner member 423a. In other words, the surface direction (SD-axial direction) may be a shaft direction extending in a radial direction on the widest surface of the bottom member 41.

Among the third connection members 423, the inner member 423a, the outer member 423b, and the connection member 423c of the third connection members 423 formed to extend a pitch may be implemented as follows.

First, the inner member 423a may be formed by extending from the first surface 413a of the third bottom member 413 to the second surface 413b of the third bottom member 413. The inner member 423a may be disposed to be exposed toward the first surface 413a of the third bottom member 413. Accordingly, the inner member 423a may be disposed to be electrically connectable to the first connection member 421. The inner member 423a may be disposed not to be exposed toward the second surface 413b of the third bottom member 413. In this case, the inner member 423a may be inserted into and disposed at the third bottom member 413 so as to be exposed only from the first surface 413a of the third bottom member 413.

Next, the outer member 423b may be formed by extending from the second surface 413b of the third bottom member 413 to the first surface 413a of the third bottom member 413. In this case, the outer member 423b may be disposed to be exposed toward the second surface 413b of the third bottom member 413. Accordingly, the outer member 423b may be disposed to be electrically connectable to the second connection member 422. The outer member 423b may be disposed to be exposed toward the first surface 413a of the third bottom member 413. In this case, the outer member 423b may be inserted into the third bottom member 413 to be exposed toward the second surface 413b of the third bottom member 413 and the first surface 413a of the third bottom member 413.

Next, the connection member 423c may be formed by extending in the surface direction (SD-axial direction) to be connected to the inner member 423a and the outer member 423b at the first surface 413a from the third bottom member 413. Accordingly, the third connection members 423 may widen a pitch by using the connection member 423c. The connection member 423c may be disposed to be exposed toward the first surface 413a of the third bottom member 413. The connection member 423c may be disposed not to be exposed toward the second surface 413b of the third bottom member 413. In this case, the connection member 423c may be inserted into and disposed at the third bottom member 413 so as to be exposed only from the first surface 413a of the third bottom member 413.

The connection member 423c, the outer member 423b, and the inner member 423a may be disposed to be exposed through the first surface 413a of the third bottom member 413. Accordingly, an area where the third connection members 423 are connectable at the first surface 413a of the third bottom member 413 for electrical connection may be increased, connection stability can be increased at the first surface 413a of the third bottom member 413. Meanwhile, the outer member 423b may be disposed to be exposed at the second surface 413b of the third bottom member 413. In this case, the connection member 423c and the inner member 423a may be disposed not to be exposed through the second surface 413b of the third bottom member 413. The connection member 423c, the outer member 423b, and the inner member 423a may be integrally formed.

Meanwhile, the entire third connection members 423 are disposed such that the inner member 423a and the outer member 423b are disposed at spaced location in the surface direction (SD-axial direction) of the third bottom member 413, and the connection member 423c may extend in the surface direction (SD-axial direction) and connect the inner member 423a and the outer member 423b to each other. In this case, the entire third connection member 423 may be implemented to extend a pitch.

At this point, each second connection member 422 may include an inner member 422a, an outer member 422b, and a connection member 422c.

The inner member 422a may be disposed to face each first connection member 421. When the third connection members 423are provided, the inner member 422a may be disposed to face the third connection members 423. The outer member 422b may be disposed to face the test apparatus 10. When the test process is performed, the outer member 422b may be connected to the test terminals 12 by being brought into direct contact with the test terminals 12. The connection member 422c may connect the inner member 422a and the outer member 422b to each other. Through the connection member 422c, the inner member 422a and the outer member 422b may be electrically connected to each other.

A part of the second connection members 422 may be formed such that the inner member 422a, the connection member 422c, and the outer member 422b form a straight line in a thickness direction (TD-axial direction) of the second bottom member 412. The second connection members 422 may be used to electrically connect the component terminals 202 and the test terminals 12 to each other without pitch extension.

A part of the second connection members 422 may be disposed at locations where the inner member 422a and the outer member 422b are spaced in a surface direction (SD-axial direction) of the second bottom member 412. In this case, the connection member 422c may extend in the surface direction (SD-axial direction) and connect the inner member 422a and the outer member 422b to each other. As described above, the second connection members 422 may use the connection member 422c to widen a pitch and electrically connect the component terminals 202 and the test terminals 12 to each other. Since the second bottom member 412 and the third bottom member 413 are disposed in parallel to each other, the surface direction (SD-axial direction) of the second bottom member 412 and the surface direction (SD-axial direction) of the third bottom member 413 may be disposed in parallel to each other. Meanwhile, when the third connection members 423 are provided, among the third connection members 423 and the second connection members 422, the third connection member 423 extending a pitch and the second connection member 422 extending a pitch may widen the pitches in different directions in the surface direction (SD-axial direction). In this case, the connection member 423c of the third connection members 423 and the connection member 422c of the second connection members 422 may extend in different directions in the surface direction (SD-axial direction). Meanwhile, among the third connection members 423 and the second connection members 422, the third connection member 423 extending a pitch and the second connection member 422 extending a pitch may widen the pitches in the same direction in the surface direction (SD-axial direction). A pitch extension direction of the third connection members 423 and a pitch extension direction of the second connection members 422 may be determined according to locations and arrangement form of the test terminals 12. In this case, a pitch extension direction of the third connection members 423 and a pitch extension direction of the second connection members 422 may be determined to form the outer member 422b of the second connection members 422 with the same arrangement form and at the same locations as the test terminals 12 of the test apparatus 10. For example, when the test terminals 12 are disposed in a matrix at the test socket 11, the outer member 422b of the second connection members 422 may be disposed to form a matrix.

Among the second connection members 422, the second connection member 422 extending a pitch may be formed with the inner member 422a, the outer member 422b, and the connection member 422c as described below.

First, the inner member 422a may be formed by extending from the first surface 412a of the second bottom member 412 to the second surface 412b of the second bottom member 412. The inner member 422a may be disposed to be exposed toward the first surface 413a of the third bottom member 413. Accordingly, the inner member 42wb may be disposed to be electrically connectable to the second connection member 422. When the second connection member 422 is electrically connected to the third connection member 423, the inner member 422a may be disposed to be connected to the outer member 423b of the third connection member 423. The inner member 422a may be disposed not to be exposed toward the second surface 413b of the third bottom member 413. In this case, the inner member 422a may be inserted into and disposed at the third bottom member 413 so as to be exposed only from the first surface 413a of the third bottom member 413.

Next, the inner member 422a may be formed by extending from the second surface 412b of the second bottom member 412 to the first surface 412a of the second bottom member 412. In this case, the outer member 422b may be disposed to be exposed toward the second surface 413b of the second bottom member 412. Accordingly, the outer member 422b may be disposed to be connected in contact with the test terminals 12. The outer member 422b may be disposed to be exposed toward the first surface 412a of the second bottom member 412. In this case, the outer member 422b may be inserted into the second bottom member 412 to be exposed toward the second surface 412b of the second bottom member 412 and the first surface 412a of the second bottom member 412.

Next, the connection member 422c may be formed by extending in the surface direction (SD-axial direction) to be connected to the inner member 422a and the outer member 422b at the first surface 412a from the second bottom member 412. Accordingly, a pitch between the second connection members 422 may extend using the connection member 422c. The connection member 422c may be disposed to be exposed toward the first surface 412a of the second bottom member 412. The connection member 422c may be disposed not to be exposed toward the second surface 412b of the third bottom member 412. In this case, the connection member 422c may be inserted into and disposed at the third bottom member 412 so as to be exposed only from the first surface 412a of the second bottom member 412.

The connection member 422c, the outer member 422b, and the inner member 422a may be disposed to be exposed through the first surface 412a of the second bottom member 412. Accordingly, an area where the third connection members 422 can connectable at the first surface 412a of the second bottom member 412 for electrical connection may be increased, connection stability can be increased at the first surface 412a of the second bottom member 412. When the second connection members 422 are electrically connected to the third connection members 423, the second connection members 422 may implement a connectable area to the outer member 423b of the third connection members 423 with the inner member 422a, the connection member 422c, and the outer member 422b. Meanwhile, the outer member 422b may be disposed to be exposed at the second surface 412b of the second bottom member 412. In this case, the connection member 422c and the inner member 422a may be disposed not to be exposed through the second surface 412b of the second bottom member 412. Accordingly, since the second surface 412b of the second bottom member 412 may reduce an area where the third connection members 423 are exposed, a risk of shorting, etc. due to the third connection members 423. The connection member 422c, the outer member 422b, and the inner member 422a may be integrally formed.

Meanwhile, the entire second connection members 422 are disposed such that the inner member 422a and the outer member 422b are disposed at spaced location in the surface direction (SD-axial direction) of the second bottom member 412, and the connection member 422c may extend in the surface direction (SD-axial direction) and connect the inner member 422a and the outer member 422b to each other. In this case, the entire second connection member 422 may be implemented to extend a pitch.

At this point, each first connection member 421 may include an inner member 421a, an outer member 421b, and a connection member 421c.

The inner member 421a may be disposed to face the electronic component 20. When the test process is performed, the inner member 421a may be connected to the component terminals 202 and brought in direct contact with the component terminals 202. The outer member 421b may be disposed to face each second connection member 422. When the third connection members 423 are provided, the inner member 421a may be disposed to face the third connection members 423. The connection member 421c may connect the inner member 421a and the outer member 421b to each other. Through the connection member 421c, the inner member 421a and the outer member 421b may be electrically connected to each other.

A part of the first connection members 421 may be formed such that the inner member 421a, the connection member 421c, and the outer member 421b form a straight line in a thickness direction (TD-axial direction) of each first bottom member 411. The first connection members 421 may be used to electrically connect the component terminals 202 and the test terminals 12 to each other without pitch extension. Each first connection member 421 may be configured with the inner member 421a, the outer member 421b, and the connection member 421c as described below.

First, the inner member 421a may be formed by extending from the first surface 411a of the first bottom member 411 to the second surface 411b of the first bottom member 411. The inner member 421a may be disposed to be exposed toward the first surface 411a of the first bottom member 411. Accordingly, the inner member 421a may be disposed to be electrically connectable to the electronic component 20. In this case, the inner member 421a may be connected to the component terminals 202 by being in directly contact with the component terminals 202. The connection member 421c may be disposed not to be exposed toward the second surface 411b of the first bottom member 411. In this case, the connection member 421c may be inserted into and disposed at the first bottom member 411 so as to be exposed only from the first surface 411a of the first bottom member 411.

Next, the outer member 421b may be formed by extending from the second surface 411b of the first bottom member 413 to the first surface 411a of the first bottom member 411. In this case, the outer member 421b may be disposed to be exposed toward the second surface 411b of the first bottom member 411. Accordingly, the outer member 421b may be disposed to be electrically connectable to the second connection member 422. When the first connection member 421 is electrically connected to the third connection member 423, the outer member 421b may be disposed to be connectable to the inner member 423a of the third connection member 423. The outer member 421b may be disposed not to be exposed toward the first surface 411a of the first bottom member 411. In this case, the outer member 421b may be inserted into and disposed at the first bottom member 411 so as to be exposed only from the second surface 411a of the first bottom member 411.

Next, the connection member 421c may extend in the thickness direction (TD-axial direction) of the first bottom member 411. Based on the thickness direction (TD-axial direction) of the first bottom member 411, the connection member 421c may be disposed between the inner member 421a and the outer member 421b. The connection member 421c may be connected to both the inner member 421a and the outer member 421b. The connection member 421c may be disposed by being inserted into the first bottom member 411 not to be exposed to the first surface 411a of the first bottom member 411 and the second surface 411b of the first bottom member 411.

As described above, the inner member 421a may be exposed through only the first surface 411a of the first bottom member 411. Accordingly, a risk of shorting, etc. due to the first connection members 421 may be reduced by reducing an area where the first connection members 421 are exposed at the first surface 411b of the first bottom member 411. The connection member 421c, the outer member 421b, and the inner member 421a may be integrally formed with each other.

Meanwhile, a part of the first connection members 422 may be disposed such that the inner member 421a and the outer member 421b are disposed at spaced location in the surface direction (SD-axial direction) of the first bottom member 411, and the connection member 421c may extend in the surface direction (SD-axial direction) and connect the inner member 421a and the outer member 421b to each other. In this case, a part of the third connection members 423 may be implemented to extend a pitch.

Meanwhile, each inner member 421a may be formed to protrude from the first surface 411a of the first bottom member 411 toward the component terminal 202. Accordingly, according to the present disclosure, the test handler 100 may improve the stability and accuracy of the connection between the component terminals 202 and the first connection members 421. Furthermore, as shown in FIG. 5, in the case of the electronic component 20 in which the component terminals 202 are disposed, the inner member 421a may be inserted into the electronic component 20 and connected to the component terminals 202. Therefore, according to the present disclosure, the test handler 100 may improve the generality of being applicable to the electronic component 20 in which the component terminals 202 are disposed.

As described above, the connection members 42 coupled to the bottom members 41 may be implemented as electrodes that are connected for each group and electrically connect the component terminals 202 and the test terminals 12. Among the electrodes, a first electrode 42a and the second electrode 42b may be formed to increase a pitch. At least one of the connection members 42 of the first electrode 42a may extend in the surface direction (SD-axial direction) to widen a pitch, and at least one of the connection members 42 of the second electrode 42b may extend in the surface direction (SD-axial direction) to widen a pitch. In this case, the first electrode 42a and the second electrode 42b may be implemented such that at least one of the extending directions, extending lengths, and shapes for widening the pitch is different from each other. The bottom unit 4 may include a plurality of first electrodes 42a and a plurality of second electrodes 42b. Meanwhile, among the electrodes, a third electrode 42c may be formed by linearly extending in the thickness direction (TD-axial direction). In this case, the third electrode 42c may electrically connect the component terminals 202 and the test terminals 12 to each other without pitch extension. The bottom unit 4 may be implemented to include only electrode 42a and 42c widening a pitch.

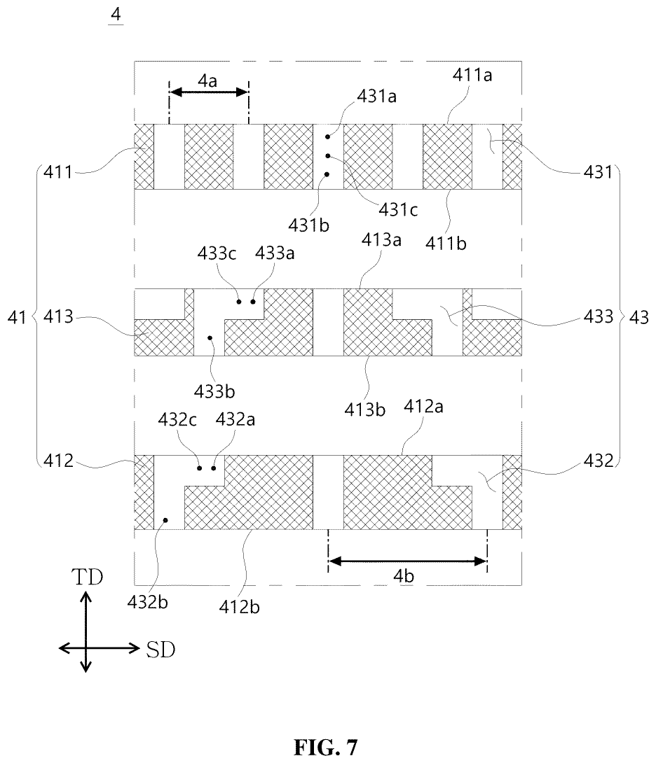

Referring to FIGS. 1 to 7, the bottom unit 4 may include a plurality of bottom holes 43.

The bottom holes 43 may be formed through the bottom members 41. The bottom holes 43 may penetrate through the bottom members 41 in the thickness direction (TD-axial direction). Each of the bottom members 41 may include the plurality of the bottom holes 43. The connection members 42 may be inserted into the bottom holes 43 and coupled to the bottom members 41. The bottom holes 43 may be formed in the same shape and size as the shape and size of the connection members 42.

Among the bottom holes 43, first bottom holes 431 may be formed through the first bottom member 411. The first connection members 421 may be respectively inserted into the first bottom holes 431. When each of the first connection members 421 includes the inner member 421a, the outer member 421b, and the connection member 421c, each of the first bottom holes 431 may include an inner hole 431a into which the inner member 421a is inserted, an outer hole 431b in which the outer member 421b is inserted, and a connection hole 431c into which the connection member 421c is inserted. The inner hole 431a, the outer hole 431b, and the connection hole 431c may be formed in the same shape and size as the inner member 421a, the outer member 421b, and the connection member 421c. The inner hole 431a, the outer hole 431b, and the connection hole 431c may be formed to be connected to communicate with each other.

Among the bottom holes 43, second bottom holes 432 may be formed through the second bottom member 412. The second connection members 422 may be respectively inserted into the second bottom holes 432. When each of the second connection members 422 includes the inner member 422a, the outer member 422b, and the connection member 422c, each of the second bottom holes 432 may include an inner hole 432a into which the inner member 422a is inserted, an outer hole 432b in which the outer member 422b is inserted, and a connection hole 432c into which the connection member 422c is inserted. The inner hole 432a, the outer hole 432b, and the connection hole 432c may be formed in the same shape and size as the inner member 422a, the outer member 422b, and the connection member 422c. The inner hole 432a, the outer hole 432b, and the connection hole 432c may be formed to be connected to communicate with each other.

Among the bottom holes 43, third bottom holes 433 may be formed through the third bottom member 413. The third connection members 423 may be respectively inserted into the third bottom holes 433. When each of the third connection members 423 includes the inner member 423a, the outer member 423b, and the connection member 423c, each of the third bottom holes 433 may include an inner hole 433a into which the inner member 423a is inserted, an outer hole 433b in which the outer member 423b is inserted, and a connection hole 433c into which the connection member 423c is inserted. The inner hole 433a, the outer hole 433b, and the connection hole 433c may be formed in the same shape and size as the inner member 423a, the outer member 423b, and the connection member 423c. The inner hole 433a, the outer hole 433b, and the connection hole 433c may be formed to be connected to communicate with each other.

As described above, when the connection members 42 are coupled to the bottom members 41 by inserting the connection members 42 into the bottom holes 43, the connection members 42 may be formed using gold power. The connection members 42 may electrically connect the component terminals 202 and the test terminals 12 to each other by using the conductive property of the gold power. Likewise, according to the present disclosure, the test handler 100 may implement the connection members 42 that can widen a pitch by filling a conductive material containing gold powder into the bottom holes 43. Therefore, according to the present disclosure, in widening the component pitch 4a into the test pitch 4b by using the bottom unit 4, the test handler 100 may improve the ease of manufacturing the bottom unit 4 with respect to the bottom unit 4 and reduce the manufacturing costs. The connection members 42 may be formed by filling gold powder and an insulating elastic material into the bottom holes 43. For example, the insulating elastic material may be liquid silicon rubber. Meanwhile, micro adjustment for a pitch between the connection members 42 formed using gold powder may be performed by resistor coating after masking.

The connection members 42 may be formed using at least one of gold powder, magnetic powder, and conductive powder. For example, the conductive powder may be at least one of conductive polymer powder, conductive metal powder, and surface treatment powder. In this case, the conductive powder may be nickel-coated polymer powder. The conductive metal powder may be silver-coated copper powder, silver-coated nickel powder, etc. The surface treatment powder may be metal powder on which surface is processed. For example, magnetic powder may be at least one of sendust powder, carbonyliron (CIP) powder, and soft magnetic powder. The connection members 42 may be formed of a mixed material formed by mixing an elastomer to at least one of gold powder, magnetic powder, and conductive powder. Furthermore, the connection members 42 may be formed to include additional highly elastic conductive wire.

Meanwhile, each third bottom hole 433 may be formed to have a larger diameter than each first bottom hole 431. Each third connection member 423 may be formed to have the same diameter as each third bottom hole 433, and each first connection member 421 may be formed to have the same diameter as each first bottom hole 431. Accordingly, according to the present disclosure, the test handler 100 may reduce a risk of shorting at portions where the first connection members 421 and the component terminals 202 are connected to each other, and increase contact areas of portions where the third connection members 423 and the test terminals 12 are connected to each other. For example, a diameter of each third bottom hole 433 may be formed larger than or equal to 0.2 mm and less than 0.5 mm, and a diameter of each first bottom hole 431 may be formed larger than or equal to 0.06 mm and less than 0.1 mm. The second bottom holes 432 may be formed to have a larger diameter than each first bottom hole 431. In this case, each of the second bottom holes 432 and each of the third bottom holes 433 may be formed to have the same diameter. Each of the second bottom holes 432 may be formed to have a diameter greater than each of the first bottom holes 431 and less than equal to or less than the third bottom holes 433.

At this point, each of the bottom members 41 may be formed using glass. In this case, the carrier main body 31 may be formed using fiber glass. Accordingly, according to the present disclosure, test handler 100 may reduce thermal expansivity between the carrier main body 31 a at the bottom members 41. Therefore, according to the present disclosure, the test handler 100 may be implemented to maintain the firmly coupled state between the carrier main body 31 and the bottom members 41 even when heat is transmitted to the bottom members 41 due to heating for adjusting the temperature of the electronic component 20 to the test temperature and heat emitted in the electronic component 20 in a process of performing the test process. Furthermore, according to the present disclosure, the test handler 100 may reduce a difference in thermal expansivity between the electronic component 20 and the bottom members 41. Accordingly, according to the present disclosure, the test handler 100 may be configured such that the connection members 42 may firmly maintain electrically connecting the component terminals 202 and the test terminals 12 to each other even when heat is transmitted to the bottom members 41 due to heating or emitting heat in the test process. Therefore, according to the present disclosure, the test handler 100 may improve the stability and accuracy of electrical connection between the component terminals 202 and the test terminals 12, so the reliability of test results of the test process can be improved.

Meanwhile, in the case of a first comparative example in which each of the bottom members 41 is made of synthetic resin such as a film, etc., the bottom members 41 are more likely to be deformed with continuous use due to the thinness of the film. Furthermore, in the first comparative example, the bottom members 41 have difficulty responding to micro pitches due to laser-induced thermal deformation, etc., when the bottom holes 43 are formed in the film. Accordingly, in the first comparative example, the accuracy of the electrical connection between the component terminals 202 and the test terminals 12 may be reduced. In the second embodiment in which each of the bottom members 41 is formed of ceramic, due to high thermal expansivity, by heating or emitting heat in the test process, coupling between the bottom members 41 and the carrier main body 31 is released, or there is a risk of poor connection between the electronic component 20 and the connection members 42. Furthermore, the second comparative example may have a risk of easily damaging the bottom members 41 due to an impact because of high fragility of the bottom members 41.

Otherwise, in the test handler 100 according to the present disclosure, each of the bottom members 41 is made of glass, so even when heating or emitting het occur in the test process, it is possible to realize maintaining firm coupling between the bottom members 41 and the carrier main body 31, improvement of connecting stability between the electronic component 20 and the connection members 42, and increasing durability to prevent damage easily caused due to an impact, etc. Furthermore, according to the present disclosure, the test handler 100 may reduce laser-induced thermal deformation when the bottom holes 43 are processed, and responsive ability with respect to a micro pitch can be improved. Each of the bottom members 41 may be formed to have a thickness greater than or equal to 0.1 mm less than 0.2 mm based on the thickness direction (TD-axial direction).

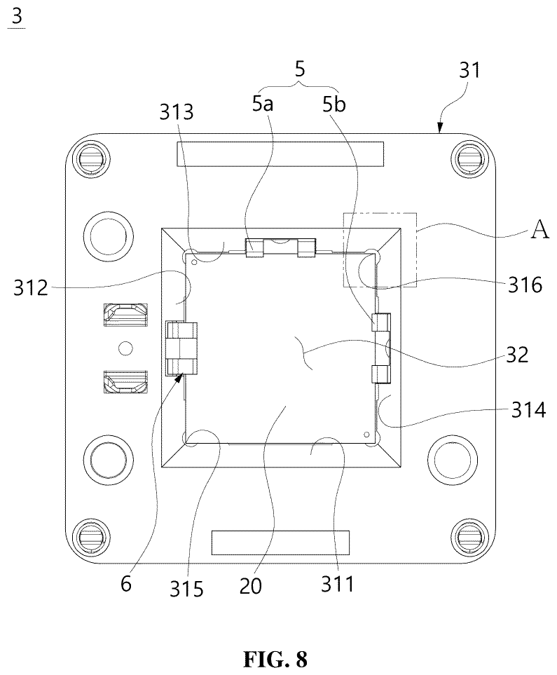

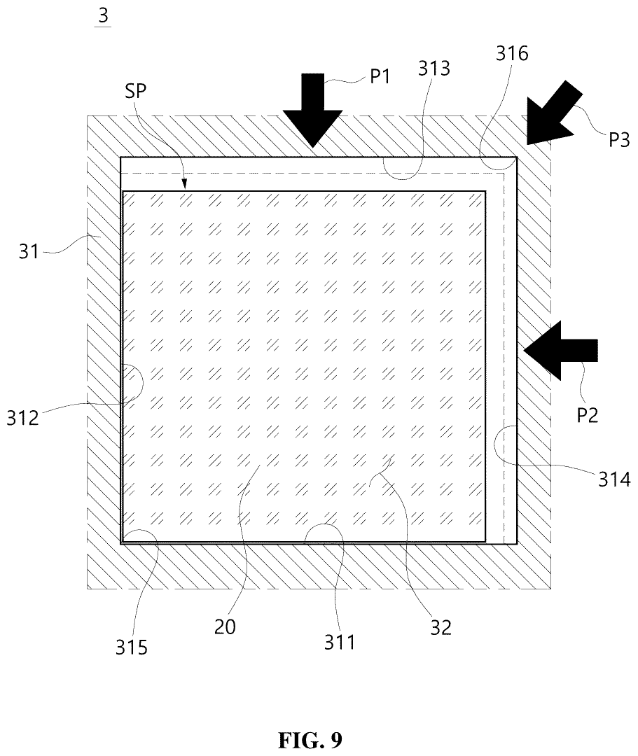

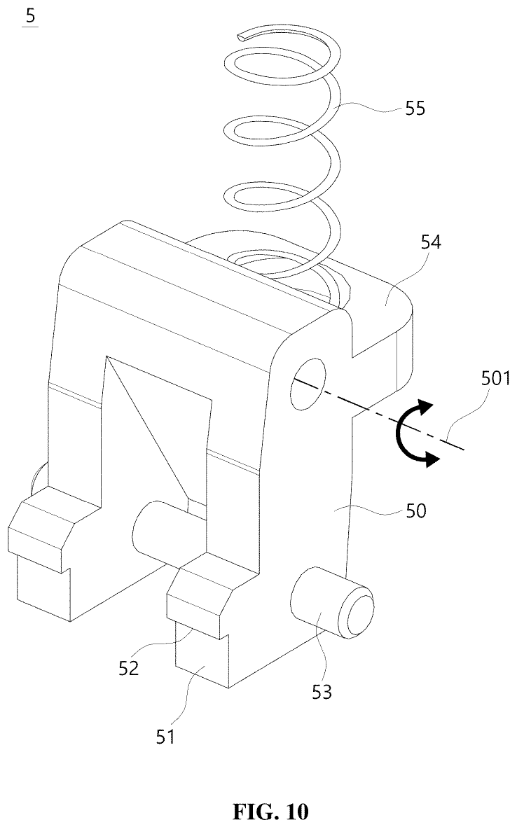

Referring to FIGS. 1 to 12, the carrier module 3 may include an alignment unit 5.

The alignment unit 5 may be coupled to the carrier main body 31. The alignment unit 5 may move the electronic component 20 stored in the storage groove 32 to a standard position SP. The standard position SP may be a position of the electronic component 20 where the component terminals 202 are respectively connected to the connection members 42. In this case, the storage groove 32 may be formed to have an area larger than the electronic component 20 based on a surface direction of the electronic component 20. Accordingly, since there is no need to accurately match the area of the storage groove 32 and the area of the electronic component 20, the test handler 100 according to the present disclosure may be implemented in such a way that it is not necessary to strictly limit a processing tolerance in the manufacture of the carrier main body 31. Therefore, according to the present disclosure, the test handler 100 may improve the ease of the manufacturing process of the carrier module 3 and reduce the manufacturing costs of the carrier module 3. Furthermore, even when the area of the storage groove 32 is formed larger than the area of the electronic component 20, the test handler 100 according to the present disclosure may move the electronic component 20 to the standard position SP by using the alignment unit 5 so that the component terminals 202 may be respectively connected to the connection members 42. Therefore, the test handler 100 according to the present disclosure may improve the accuracy of the test process, improving the reliability of the test results of the test process.

Meanwhile, the area of the storage groove 32 may be a sectional area based on the surface direction (SD-axial direction). When the storage groove 32 extends in a depth direction toward the bottom unit 4 and a sectional area is changed, the area of the storage groove 32 may be an area of a portion corresponding to a depth of the electronic component 20 when the electronic component 20 is supported by the bottom unit 4. Therefore, when the electronic component 20 is supported by the bottom unit 4, a part of the inner surface of the carrier main body 31 facing the storage groove 32 may be disposed to be spaced from the electronic component 20.

The alignment unit 5 may be configured to locate the electronic component 20 stored in the storage groove 32 at the standard position SP by bringing the electronic component 20 stored in the storage groove 32 into close contact with both a first facing surface 311 and a second facing surface 312 of the carrier main body 31. The first facing surface 311 and the second facing surface 312 may be disposed to be connected to each other, among the inner surfaces of the carrier main body 31 disposed to face the storage groove 32. For example, in the case of the storage groove 32 having a quadrilateral section based on the surface direction (SD-axial direction), the carrier main body 31 may include a third facing surface 313 disposed to face the first facing surface 311 and a fourth facing surface 314 disposed to face the second facing surface 312. In this case, the alignment unit 5 may move the electronic component 20 stored in the storage groove 32 toward a first corner unit 315 where the first facing surface 311 and the second facing surface 312 are connected to each other, bringing the electronic component 20 stored in the storage groove 32 into close contact with both the first facing surface 311 and the second facing surface 312. Meanwhile, the first corner unit 315 may be an edge formed by connecting the first facing surface 311 and the second facing surface 312 to each other. The first corner unit 315 may be a curved surface. A groove and the like may be formed in the first corner unit 315. Meanwhile, a second corner unit 316 may be disposed at a portion where the third facing surface 313 and the fourth facing surface 314 are connected to each other. The second corner unit 316 and the first corner unit 315 may be disposed to face each other in a diagonal direction of the storage groove 32.

The alignment unit 5 may locate the electronic component 20 stored in the storage groove 32 at the standard position SP by moving the electronic component 20 stored in the storage groove 32 in a first direction (direction of arrow P1) and a second direction (direction of arrow P2). The first direction (direction of arrow P1) may be a direction from the third facing surface 313 toward the first facing surface 311. The second direction (direction of arrow P2) may be a direction from the fourth facing surface 314 toward the second facing surface 312. The alignment unit 5 may move the electronic component 20 stored in the storage groove 32 to the first direction (direction of arrow P1) so that the electronic component 20 is brought into close contact with the first facing surface 311, and move the electronic component 20 stored in the storage groove 32 to the second direction (direction of arrow P2) so that the electronic component 20 is brought into close contact with the second facing surface 312. In this case, moving toward the first direction (direction of arrow P1) and moving toward the second direction (direction of arrow P2) allow the alignment unit 5 to move the electronic component 20 stored in the storage groove 32 in a third direction (direction of arrow P3). The third direction (direction of arrow P3) may be a diagonal direction from the second corner unit 316 to the first corner unit 315. Accordingly, the alignment unit 5 may move the electronic component 20 stored in the storage groove 32 toward the first corner unit 315 so that the electronic component 20 may be located at the standard position SP. Meanwhile, when the test process is performed with the tray 1 standing upright, the first corner unit 315 may be located at a lower end of the storage groove 32. Accordingly, the test handler 100 according to the present disclosure may maintain the electronic component 20 to be located at the standard position SP by using support force by the alignment unit 5 and force of gravity acting on the electronic component 20 when the test process is performed. Therefore, the test handler 100 according to the present disclosure may improve the accuracy of the test process. The first corner unit 315 may be located at a left end of the lower end of the storage groove 32 or a right end of the lower end of the storage groove 32.

A plurality of alignment units 5 may be coupled to the carrier main body 31. Among the alignment units 5, a first alignment unit 5a may move the electronic component 20 stored in the storage groove 32 in the first direction (direction of arrow P1), so that the electronic component 20 stored in the storage groove 32 is brought into close contact with the first facing surface 311. The first alignment unit 5a may be coupled to the carrier main body 31 so as to be disposed at the third facing surface 313. Among the alignment units 5, a second alignment unit 5b may move the electronic component 20 stored in the storage groove 32 in the second direction (direction of arrow P2), so that the electronic component 20 stored in the storage groove 32 is brought into close contact with the second facing surface 312. The second alignment unit 5b may be coupled to the carrier main body 31 so as to be disposed at the fourth facing surface 314. Likewise, the test handler 100 according to the present disclosure moves the electronic component 20 stored in the storage groove 32 in the first direction (direction of arrow P1) by using the first alignment unit 5a, and moves the electronic component 20 in the second direction (direction of arrow P2) by using the second alignment unit 5b, so that the electronic component 20 stored in the storage groove 32 is located at the standard position SP. The second alignment unit 5b and the first alignment unit 5a may be formed to match with each other without a location disposed at the carrier main body 31 and a direction of moving the electronic component 20 stored in the storage groove 32.

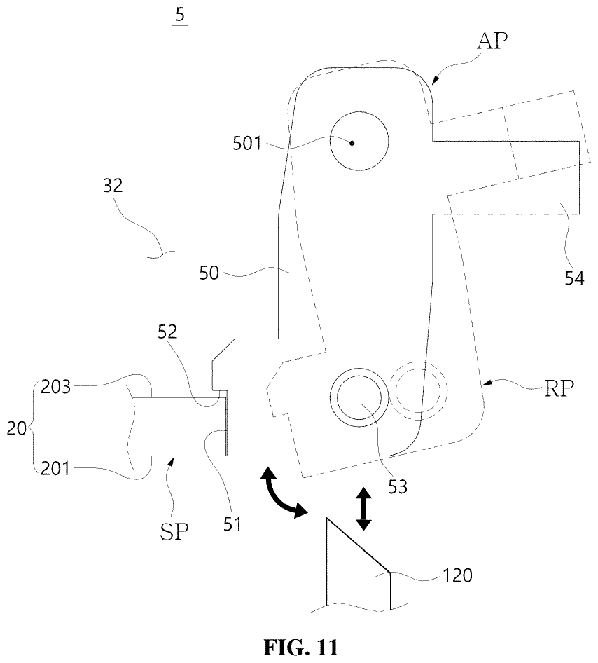

The alignment unit 5 may be coupled to the carrier main body 31 rotatably between an avoidance position RP (indicated with a dotted line in FIG. 11) and an alignment position AP (indicated with a solid line in FIG. 11). The alignment unit 5 may be located at the avoidance position RP and open the storage groove 32. Accordingly, when the electronic component 20 is loaded on the storage groove 32 and the electronic component 20 is unloaded from the storage groove 32, the alignment unit 5 may be disposed not to interfere with the electronic component 20. In this case, the alignment unit 5 located at the avoidance position RP may be entirely inserted into the carrier main body 31. After the electronic component 20 is loaded on the storage groove 32, the alignment unit 5 may be rotated from the avoidance position RP to the alignment position AP and move the electronic component 20 stored in the storage groove 32 to the standard position SP. A portion of the alignment unit 5 located at the alignment position AP may protrude from the carrier main body 31 toward the storage groove 32. The alignment unit 5 may be rotated between the avoidance position RP and the alignment position AP on a rotation shaft 501. The rotation shaft 501 may be implemented in a shaft that is rotatably coupled to the carrier main body 31.

The alignment unit 5 may include an alignment surface 51.

The alignment surface 51 may be a surface of the alignment unit 5 disposed to face the storage groove 32. When the alignment unit 5 is rotated from the avoidance position RP to the alignment position AP with the electronic component 20 loaded on the storage groove 32, the alignment surface 51 may be brought into direct contact with the electronic component 20 stored in the storage groove 32 and move the electronic component 20 stored in the storage groove 32 to the standard position SP. In this case, the alignment surface 51 may move the electronic component 20 stored in the storage groove 32 by pushing a side surface thereof. When the alignment unit 5 is located at the alignment position AP, the alignment surface 51 may be disposed in parallel to the side surface of the electronic component 20 stored in the storage groove 32. The alignment surface 51 may be formed into a flat surface.

The alignment unit 5 may include a limitation surface 52.

The limitation surface 52 may protrude from the alignment surface 51 toward the electronic component 20 stored in the storage groove 32. The limitation surface 52 may be disposed above an upper surface 203 of the electronic component 20 located at the standard position SP. At this point, the upper surface 203 of the electronic component 20 is a surface opposite to the bottom surface 201 of the electronic component 20. When the loading process and the unloading process are performed to the tray 1 lying horizontally, the upper surface 203 of the electronic component 20 may be disposed in an upward direction. In this case, the limitation surface 52 may be disposed in the upward direction with respect to the upper surface 203 of the electronic component 20 located at the standard position SP. When the test process is performed to the tray 1 standing vertically, the upper surface 203 of the electronic component 20 may be disposed to face the front side (direction of arrow FD). In this case, the limitation surface 52 may be disposed at the front side with respect to the upper surface 203 of the electronic component 20 located at the standard position SP. Meanwhile, when the upper surface 203 of the electronic component 20 is disposed toward the front side (direction of arrow FD) in performing the test process, the bottom surface 201 of the electronic component 20 may be disposed toward the rear side (direction of arrow BD).

The limitation surface 52 is disposed above the upper surface 203 of the electronic component 20 located at the standard position SP, thereby limiting a movable distance where the electronic component 20 located at the standard position SP is moved in a removal direction from the storage groove 32. Therefore, the test handler 100 according to the present disclosure may use the alignment unit 5 to improve the accuracy of the test process and simultaneously improve the stability of the test process. The limitation surface 52 may be a surface of the alignment unit 5 disposed to face the storage groove 32. When the alignment unit 5 is rotated from the avoidance position RP to the alignment position AP with the electronic component 20 loaded on the storage groove 32 so that the alignment surface 51 is brought into contact with the electronic component 20 stored in the storage groove 32, the limitation surface 52 may be disposed above the upper surface 203 of the electronic component 20. In this case, the limitation surface 52 may be disposed in contact with the upper surface 203 of the electronic component 20. When the alignment unit 5 is located at the alignment position AP, the limitation surface 52 may be disposed in parallel to the upper surface of the electronic component 20 stored in the storage groove 32. The limitation surface 52 may be formed into a flat surface.

The alignment unit 5 may include an operation member 53, a support member 54, and an elastic member 55.

The operation member 53 may be used to move the alignment unit 5 to the avoidance position RP. The operation member 53 may be disposed to protrude from an alignment main body 50 included in the alignment unit 5. When the alignment unit 5 is rotated between the avoidance position RP and the alignment position AP on the rotation shaft 501, the operation member 53 may protrude from the alignment main body 50 in a direction parallel to the rotation shaft 501. The alignment main body 50 may form the entire exterior of the alignment unit 5. The alignment main body 50 may be coupled to the carrier main body 31 rotatably on the rotation shaft 501. As shown in FIG. 11 with a solid line, when the alignment unit 5 is located at the alignment position AP, an opening and closing unit 120 may be disposed below the operation member 53. One portion of the opening and closing unit 120 facing the operation member 53 may be reduced in size as it extends toward the operation member 53. In this case, one portion of the opening and closing unit 120 may include a slope inclined toward the storage groove 32 as it extends toward the operation member 53. When the opening and closing unit 120 is raised toward the operation member 53, the opening and closing unit 120 may pressurize the operation member 53 by using the slope. Accordingly, the alignment unit 5 may be located at the avoidance position RP by being rotated on the rotation shaft 501. With the alignment unit 5 located at the avoidance position RP, when the opening and closing unit 120 is lowered and spaced apart from the operation member 53, the alignment unit 5 is located at the alignment position AP by being located on the rotation shaft 501. In this case, the alignment unit 5 may be rotated using the elastic force of the elastic member 55 and located at the alignment position AP.

The opening and closing unit 120 may be provided at the loading unit 200. While the opening and closing unit 120 presses the operation member 53 so that the alignment unit 5 is rotated to the avoidance position RP, the loading unit 200 may load the electronic component 20 on the storage groove 32. When the electronic component 20 is loaded on the storage groove 32, the opening and closing unit 120 may be spaced apart from the operation member 53. Accordingly, the alignment unit 5 may be rotated to the alignment position AP, and move the electronic component 20 stored in the storage groove 32 to the standard position SP.

The opening and closing unit 120 may be provided in the unloading unit 400. While the opening and closing unit 120 presses the operation member 53 so that the alignment unit 5 is rotated to the avoidance position RP, the unloading unit 400 may unload the electronic component 20 from the storage groove 32. When the electronic component 20 is unloaded from the storage groove 32, the opening and closing unit 120 may be spaced apart from the operation member 53. Accordingly, the alignment unit 5 may be rotated to the alignment position AP.

The support member 54 may protrude from the alignment main body 50. The support member 54 may support the elastic member 55. A first portion of the elastic member 55 may be supported by the support member 54, and a second portion of the elastic member 55 may be supported by the carrier main body 31. Based on FIG. 11, a lower portion of the elastic member 55 may be supported by the support member 54 and an upper portion of the elastic member 55 may be supported by the carrier main body 31. When the opening and closing unit 120 presses the operation member 53 so that the alignment unit 5 is rotated to the avoidance position RP, the support member 54 may push and compress the elastic member 55 by being rotated on the rotation shaft 501. Thereafter, when the opening and closing unit 120 is spaced apart from the operation member 53, the elastic member 55 may be tensioned and rotate the support member 54 on the rotation shaft 501. Accordingly, the alignment unit 5 may be located at the alignment position AP. Although not shown in the drawing, the elastic member 55 may be coupled to a shaft constituting the rotation shaft 501. In this case, the elastic member 55 may be a torsion spring.

Referring to FIGS. 1 to 13, the alignment unit 5 according to a deformed embodiment may include a first alignment surface 51a and a second alignment surface 51b.

The first alignment surface 51a may move the electronic component 20 stored in the storage groove 32 toward the first facing surface 311. The first alignment surface 51a may move the electronic component 20 stored in the storage groove 32 in the first direction (direction of arrow P1), so that the electronic component 20 stored in the storage groove 32 is brought into close contact with the first facing surface 311.

The second alignment surface 51b may move the electronic component 20 stored in the storage groove 32 toward the second facing surface 312. The second alignment surface 51b may move the electronic component 20 stored in the storage groove 32 in the second direction (direction of arrow P2), so that the electronic component 20 stored in the storage groove 32 is brought into close contact with the second facing surface 312.

The second alignment surface 51b and the first alignment surface 51a may be provided at the alignment main body 50. Accordingly, the alignment unit 5 may move the electronic component 20 stored in the storage groove 32 to the third direction (direction of arrow P3) by using the second alignment surface 51b and the first alignment surface 51a, so that the electronic component 20 stored in the storage groove 32 may be brought into close contact with both the first facing surface 311 and the second facing surface 312. Therefore, the test handler 100 according to the present disclosure may be configured to locate the electronic component 20 stored in the storage groove 32 at the standard position SP by using a single alignment unit 5. Accordingly, in comparison to the embodiment of moving the electronic component 20 stored in the storage groove 32 to the standard position SP by using the first alignment unit 5a and the second alignment unit 5b, the deformed embodiment of moving the electronic component 20 stored in the storage groove 32 to the standard position SP by using the first alignment surface 51a and the second alignment surface 51b may reduce the number of alignment units 5 provided in the carrier module 3.

The alignment unit 5 according to the deformed embodiment may be coupled to the carrier main body 31 so that the alignment unit 5 is disposed at the second corner unit 316. In this case, the first alignment surface 51a may be disposed at the third facing surface 313. The first alignment surface 51a may be formed into a flat surface in parallel to the first facing surface 311. The second alignment surface 51b may be disposed at the fourth facing surface 314. The second alignment surface 51b may be formed into a flat surface in parallel to the second facing surface 312. The alignment unit 5 according to the deformed embodiment may be coupled to the carrier main body 31 so that the alignment unit 5 is movable in a fourth direction opposite to the third direction (direction of arrow P3) and the third direction (direction of arrow P3). In this case, the alignment unit 5 according to the deformed embodiment may be coupled to the carrier main body 31 so that the alignment unit 5 is movable linearly in the third direction (direction of arrow P3) and the fourth direction.

According to the deformed embodiment, the alignment unit 5 may include the support member 54, the elastic member 55, and an operation hole 56.

The support member 54 may protrude from the alignment main body 50. The support member 54 may protrude from the alignment main body 50 in a direction perpendicular to the third direction (direction of arrow P3), and protrude from the protrusion in the fourth direction. The support member 54 may support the elastic member 55. The alignment unit 5 according to the deformed embodiment may include a plurality of support members 54. In this case, the support members 54 and 54′may protrude from opposite portions of the alignment main body 50 in a direction perpendicular to the third direction (direction of arrow P3).

The elastic member 55 may be supported by the support member 54 and the carrier main body 31. A first portion of the elastic member 55 may be supported by the support member 54, and a second portion of the elastic member 55 may be supported by the carrier main body 31. A portion of the support member 54 may be inserted into the elastic member 55. The elastic member 55 may be disposed in parallel to the third direction (direction of arrow P3). When a plurality of support members 54 is provided, the alignment unit 5 according to the deformed embodiment may include a plurality of elastic members 55. The elastic members 55 and 55′may be respectively supported by the support members 54 and 54′. Based on the direction perpendicular to the third direction (direction of arrow P3), the alignment main body 50 may be disposed between the elastic members 55 and 55′.

The operation hole 56 may be formed through the alignment main body 50. The opening and closing unit 120 (shown in FIG. 11) may be disposed below the operation hole 56. When the opening and closing unit 120 is raised toward the operation hole 56, the opening and closing unit 120 may be inserted into the operation hole 56 and press the alignment main body 50 by using the slope. Accordingly, the alignment unit 5 according to the deformed embodiment may be moved in the fourth direction so that alignment unit 5 is located at the avoidance position RP. In this case, the support member 54 may push and compress the elastic member 55. When with the alignment unit 5 according to the deformed embodiment located at the avoidance position RP the opening and closing unit 120 is lowered and removed from the operation hole 56, the alignment unit 5 is moved in the third direction (direction of arrow P3) and located at the alignment position AP. In this case, the alignment unit 5 according to the deformed embodiment may be moved in the third direction (direction of arrow P3) by using an elastic force of the elastic member 55.

The alignment unit 5 according to the deformed embodiment may include a stopper 57 and a limiting groove 58.

The stopper 57 may be coupled to the carrier main body 31 so that the stopper 57 is inserted into the limiting groove 58. The stopper 57 may limit a movable distance in which the alignment unit 5 according to the deformed embodiment is moved to the third direction (direction of arrow P3). Accordingly, the test handler 100 according to the present disclosure may prevent the alignment unit 5 according to the deformed embodiment from pressing the electronic component 20 stored in the storage groove 32 with an excessive force, by using the stopper 57. The stopper 57 may limit a movable distance in which the alignment unit 5 according to the deformed embodiment is moved in the fourth direction. Accordingly, the test handler 100 according to the present disclosure may prevent the alignment unit 5 according to the deformed embodiment from being separated from the carrier main body 31, by using the stopper 57.

The limiting groove 58 may be formed at the support member 54. The stopper 57 may be inserted into the limiting groove 58, so that the stopper 57 may be disposed between supporting surfaces of the support member 54. A first support surface of the support surfaces may be disposed in the third direction (direction of arrow P3) with respect to the limiting groove 58. A second support surface of the support surfaces may be disposed in the fourth direction with respect to the limiting groove 58. When the alignment unit 5 according to the deformed embodiment is moved in the third direction (direction of arrow P3), the stopper 57 may be supported by the second support surface. Accordingly, the stopper 57 may limit a movable distance in which the alignment unit 5 according to the deformed embodiment is moved to the third direction (direction of arrow P3). When the alignment unit 5 according to the deformed embodiment is moved in the fourth direction, the stopper 57 may be supported by the first support surface. Accordingly, the stopper 57 may limit a movable distance in which the alignment unit 5 according to the deformed embodiment is moved in the fourth direction. Meanwhile, when the alignment unit 5 according to the deformed embodiment includes a plurality of support members 54, the support members 54 and 54′may each have the limiting groove 58. In this case, the stopper 57 may be disposed to be inserted into each limiting groove 58.

Referring to FIGS. 1 to 13, the carrier module 3 may include a latch unit 6.

The latch unit 6 may be coupled to the carrier main body 31. The latch unit 6 may support the electronic component 20 located at the standard position SP. Accordingly, the latch unit 6 may prevent the electronic component 20 located at the standard position SP from being removed from the storage groove 32. The latch unit 6 may be coupled to the carrier main body 31 to be rotatable between an opening position and a closing position. The latch unit 6 may be located at the opening position and open the storage groove 32. Accordingly, when the electronic component 20 is loaded on the storage groove 32 and the electronic component 20 is unloaded from the storage groove 32, the latch unit 6 may be disposed not to interfere with the electronic component 20. In this case, the latch unit 6 located at the opening position may be entirely inserted into the carrier main body 31. After the electronic component 20 is loaded on the storage groove 32, the latch unit 6 may be rotated from the opening position to the closing position and support the upper surface 302 of the electronic component 20 stored in the storage groove 32. In this case, after the alignment unit 5 is located at the alignment position AP, moving the electronic component 20, which is stored in the storage groove 32, to the standard position SP, the latch unit 6 may be located at the closing position. An operation of rotating the alignment unit 5 to the alignment position AP and an operation of rotating the latch unit 6 to the closing position may be performed at the same time. The latch unit 6 may be rotated between the opening position and the closing position on a rotating shaft (not shown). The rotating shaft of the latch unit 6 may be implemented into a shaft that is rotatably coupled to the carrier main body 31.

The latch unit 6 may include a latch main body 61 and a latch member 62.

The latch main body 61 may be coupled to the carrier main body 31. The entire latch main body 61 may be disposed in the carrier main body 31. The latch main body 61 may be coupled to the carrier main body 31 to be movable upward and downward.

The latch member 62 may be coupled to the carrier main body 31 to be rotatable between the opening position and the closing position. The latch main body 61 may be connected to the latch member 62. In this case, as the latch member 62 is raised and lowered, the latch member 62 may be rotated between the opening position and the closing position. For example, when the latch main body 61 is raised as a latch opening and closing unit (not shown) is raised, the latch member 62 may be rotated to the opening position. When the latch main body 61 is lowered as the latch opening and closing unit is lowered, the latch member 62 may be rotated to the closing position. In this case, an elastomer (not shown) may be disposed between the latch main body 61 and the carrier main body 31. The elastomer is compressed as the latch main body 61 is raised and is tensioned as the latch opening and closing unit is lowered, lowering the latch main body 61. The latch opening and closing unit may be disposed below the latch unit 6.

When the latch opening and closing unit presses the latch main body 61 to rotate the latch member 62 to the opening position, the loading unit 200 may load the electronic component 20 on the storage groove 32. The latch opening and closing unit may be provided at the loading unit 200. When the loading unit 200 loads the electronic component 20 on the storage groove 32, the latch opening and closing unit may remove a pressure with respect to the latch main body 61 and rotate the latch member 62 to the closing position. The latch opening and closing unit may be provided at the unloading unit 400. When the latch opening and closing unit presses the latch main body 61 to rotate the latch member 62 to the opening position, the unloading unit 400 may unload the electronic component 20 from the storage groove 32.

Although not shown in the drawings, the latch main body 61 and the latch member 62 are formed integrally with each other to be coupled to the carrier main body 31 to be rotatable between the opening position and the closing position. In this case, the elastomer may be coupled to the rotating shaft of the latch unit 6. The elastomer may be a torsion spring. The latch opening and closing unit may be raised to rotate the latch unit 6 to the opening position, and be lowered to rotate the latch unit 6 to the closing position.

When the carrier module 3 includes the first alignment unit 5a disposed at the third facing surface 313 and the second alignment unit 5b disposed at the fourth facing surface 314, the latch unit 6 may be coupled to the carrier main body 31 to be disposed at the first facing surface 311 or the second facing surface 312. Accordingly, the test handler 100 according to the present disclosure may be disposed so that the latch unit 6 and the alignment unit 5 do not interfere with each other. Furthermore, when the alignment unit 5 includes the limitation surface 52, the test handler 100 according to the present disclosure can prevent, with the latch unit 6 and the limitation surface 52 at different positions, the electronic component 20 stored in the storage groove 32 from being arbitrarily removed from the carrier module 3, so it is possible to improve the stability of the processes performed when the electronic component 20 is stored in the carrier module 3. The carrier module 3 may include a plurality of latch units 6. In this case, the latch units 6 may be coupled to the carrier main body 31 to be respectively disposed at the first facing surface 311 and the second facing surface 312.

When the carrier module 3 includes one alignment unit 5 disposed at the second corner unit 316, the carrier module 3 may include a plurality of latch units 6. Each of the latch units 6 may be disposed at the second facing surface 312 and the fourth facing surface 314. Accordingly, the test handler 100 according to the present disclosure may be configured such that the latch units 6 and the alignment unit 5 are disposed not to interfere with each other and the latch units 6 at different positions prevents the electronic component 20 stored in the storage groove 32 from being arbitrarily removed from the carrier module 3. Each of the latch units 6 may be disposed at the first facing surface 311 and the third facing surface 313. The latch units 6 may be disposed at each of the first facing surface 311, the second facing surface 312, the third facing surface 313, and the fourth facing surface 314.

The above-described present disclosure is not limited to the embodiment and accompanying drawings, and those skilled in the art will appreciate that various modifications, additions, and substitutions are possible, without departing from the scope and spirit of the present disclosure.

1. A carrier module provided to store an electronic component, the carrier module comprising:
a carrier main body on which a storage groove is formed to store the electronic component; and
a bottom unit coupled to the carrier main body and supporting a bottom surface of the electronic component stored in the storage groove,
wherein the bottom unit comprises:
N (N is a natural number greater than 1) bottom members; and
a plurality of connection members coupled to each bottom member, and configured to electrically connect component terminals included in the electronic component stored in the storage groove and test terminals included in a test apparatus to each other,
wherein,
first connection members among the connection members are coupled to a first bottom member among the bottom members, the first connection members are configured to be connected to the component terminals
second connection members among the connection members are coupled to a second bottom member among the bottom members, the second connection members are configured to be connected to the test terminals, and
a pitch between portions where the second connection members are connected to the test terminals is wider than a pitch between portions where the first connection members are connected to the component terminals.

2. The carrier module of claim 1, wherein the bottom unit comprises a plurality of bottom holes formed through each of the bottom members, and
the connection members are inserted into the bottom holes to be coupled to the bottom members.

3. The carrier module of claim 2, wherein each of the connection members is made using at least one of gold powder, magnetic powder, and conductive powder.

4. The carrier module of claim 1, wherein a third bottom member among the bottom members is disposed between the first bottom member and the second bottom member,
third connection members among the connection members are coupled to the third bottom member to electrically connect the first connection members and the second connection members to each other, and
each of the third connection members includes an inner member disposed toward the first connection members, an outer member disposed toward the second connection members, and a connection member connecting the inner member and the outer member to each other.

5. The carrier module of claim 4, wherein a part of the third connection members is configured such that the inner member, the connection member, and the outer member are disposed in a straight line in a thickness direction of the third bottom member.

6. The carrier module of claim 4, wherein a part of or all the third connection members are configured such that the inner member and the outer member are disposed at locations spaced from each other in a surface direction perpendicular to a thickness direction of the third bottom member, and the connection member extend in the surface direction to connect the inner member and the outer member to each other.

7. The carrier module of claim 6, wherein the inner member is formed to extend from a first surface of the third bottom member disposed toward the first connection members to a second surface of the third bottom member disposed toward the second connection members,
the outer member is formed to extend from the second surface of the third bottom member to the first surface of the third bottom member, and
the connection member is formed to expand in the surface direction on the first surface of the third bottom member to be respectively connected to the inner member and the outer member.

8. The carrier module of claim 1, wherein each of the second connection members includes an inner member disposed toward the first connection members, an outer member connected to the test terminals, and a connection member connecting the inner member and the outer member.

9. The carrier module of claim 8, wherein a part of or all of the second connection members are configured such that the inner member and the outer member are disposed at locations spaced from each other in a surface direction perpendicular to a thickness direction of the second bottom member, and the connection member extends in the surface direction to connect the inner member and the outer member to each other.

10. The carrier module of claim 9, wherein the inner member is formed to extend from a first surface of the second bottom member disposed toward the first connection members to a second surface of the second bottom member disposed toward the test terminals,
the outer member is formed to extend from the second surface of the second bottom member to the first surface of the second bottom member, and
the connection member is formed to extend in the surface direction on the first surface of the second bottom member to be respectively connected to the inner member and the outer member.

11. The carrier module of claim 1, wherein each of the first connection members includes an inner member disposed toward the component terminals, an outer member disposed toward the second connection members, and a connection member connecting the inner member and the outer member to each other, and
each inner member is formed to protrude from a first surface of the first bottom member toward the component terminals, the first surface of the first bottom member is disposed toward the component terminals.

12. The carrier module of claim 1, wherein the carrier main body is formed using fiberglass, and
each of the bottom members is formed using glass.

13. The carrier module of claim 1, further comprising:
an alignment unit coupled to the carrier main body,
wherein the storage groove is formed to have an area greater than an area of the electronic component with respect to a surface direction of the electronic component, and
the alignment unit transfers the electronic component stored in the storage groove to a reference position where the component terminals of the electronic component stored in the storage groove are connected to the connection members.

14. The carrier module of claim 13, wherein the alignment unit is rotatably coupled to the carrier main body between an avoidance position where the storage groove is opened and an alignment position where the electronic component stored in the storage groove is transferred to the reference position.

15. The carrier module of claim 13, wherein the carrier main body includes a first facing surface disposed toward the storage groove, and a second facing surface disposed in contact with the first facing surface, and
the alignment unit configured to transfer the electronic component stored in the storage groove to a first corner unit where the first facing surface and the second facing surface are connected to each other, and locating the electronic component stored in the storage groove at the reference position by bring the electronic component stored in the storage groove into close contact with both the first facing surface and the second facing surface.

16. The carrier module of claim 15, wherein a plurality of alignment units is coupled to the carrier main body,
a first alignment unit among the alignment units is disposed at a third facing surface, which is opposite to the first facing surface, and transfers the electronic component stored in the storage groove toward the first facing surface, and
a second alignment unit among the alignment units is disposed at a fourth facing surface, which is opposite to the second facing surface, and transfers the electronic component stored in the storage groove toward the second facing surface.

17. The carrier module of claim 13, wherein the alignment unit comprises an alignment surface of transferring the electronic component stored in the storage groove to the reference position, and a limitation surface protruding from the alignment surface toward the electronic component stored in the storage groove, and
the limitation surface is disposed above an upper surface of the electronic component located at the reference position.

18. The carrier module of claim 15, wherein the alignment unit comprises a first alignment surface brought into contact with the electronic component stored in the storage groove and transferring the electronic component stored in the storage groove toward the first facing surface, and a second alignment surface brought into contact with the electronic component stored in the storage groove and transferring the electronic component stored in the storage groove toward the second facing surface, and
in the carrier main body, the alignment unit is disposed at a second corner unit opposite to the first corner unit.

19. A tray comprising:
a tray main body; and
a carrier module coupled to the tray main body,
wherein the carrier module comprises:
a carrier main body in which a storage groove is formed to store the electronic component; and
a bottom unit coupled to the carrier main body and supporting a bottom surface of the electronic component stored in the storage groove,
wherein the bottom unit comprises:
N (N is a natural number greater than 1) bottom members; and
a plurality of connection members coupled to each bottom member, and configured to electrically connect component terminals included in the electronic component stored in the storage groove and test terminals included in a test apparatus to each other,
wherein,
first connection members among the connection members are coupled to a first bottom member among the bottom members, the first connection members are configured to be connected to the component terminals,
second connection members among the connection members are coupled to a second bottom member among the bottom members, the second connection members are configured to be connected to the test terminals, and
a pitch between portions where the second connection members are connected to the test terminals is wider than a pitch between portions where the first connection members are connected to the component terminals.

20. A test handler comprising:
a loading unit performing a loading process of loading an electronic component to be tested to a tray; and
a test unit performing a test process of testing the electronic component stored in the tray,
wherein the loading unit stores the electronic component to be tested, in a carrier module included in the tray,
wherein the carrier module comprises:
a carrier main body in which a storage groove is formed to store the electronic component; and
a bottom unit coupled to the carrier main body and supporting a bottom surface of the electronic component stored in the storage groove,
wherein the bottom unit comprises:
N (N is a natural number greater than 1) bottom members; and
a plurality of connection members coupled to each bottom member, and configured to electrically connect component terminals included in the electronic component stored in the storage groove and test terminals included in a test apparatus to each other,
wherein,
first connection members among the connection members are coupled to a first bottom member among the bottom members, the first connection members are configured to be connected to the component terminals
second connection members among the connection members are coupled to a second bottom member among the bottom members, the second connection members are configured to be connected to the test terminals, and
a pitch between portions where the second connection members are connected to the test terminals is wider than a pitch between portions where the first connection members are connected to the component terminals.
